(19) United States
(12) Patent Application Publication
(10) Pub. No.: US 2026/0159945 A1
(43) Pub. Date: Jun. 11, 2026

(54) EJECTION APPARATUS, SUBSTRATE PROCESSING APPARATUS, SUBSTRATE PROCESSING METHOD, METHOD OF MANUFACTURING SEMICONDUCTOR DEVICE AND NON-TRANSITORY COMPUTER-READABLE RECORDING MEDIUM

(71) Applicant: Kokusai Electric Corporation, Tokyo (JP)

(72) Inventors: Sakito NAKADE, Toyama-shi (JP); Yusaku OKAJIMA, Toyama-shi (JP)

(73) Assignee: Kokusai Electric Corporation, Tokyo (JP)

(21) Appl. No.: 19/410,092

(22) Filed: Dec. 5, 2025

(30) Foreign Application Priority Data
Dec. 5, 2024 (JP) 2024-212399

(51) Int. Cl. C23C 16/455; C23C 16/34; H10P 14/60; H10P 14/694

(52) U.S. Cl. CPC C23C 16/45548; C23C 16/345; C23C 16/45508; C23C 16/45565; H10P 14/6339; H10P 14/69433

(57) ABSTRACT

It is possible to increase a flow path area of a gas. There is provided a technique that includes: a first nozzle and a second nozzle facing a peripheral edge of a substrate and extending perpendicular to a main surface of the substrate. Each nozzle includes a front surface facing the substrate and ejection holes thereon parallel to the main surface. An angle of a normal to the front surface relative to a direction from a center of the nozzles toward a center of the substrate at positions where the ejection holes are located increases in an arrangement order of the ejection holes. An ejection hole of the first nozzle closest to the second nozzle and an ejection hole of the second nozzle closest to the first nozzle are located on a substantially same tangent plane such that the directions of gases being ejected are substantially parallel to each other.

This non-provisional U.S. patent application is based on and claims priority under 35 U.S.C. § 119 of Japanese Patent Application No. 2024-212399, filed on December 5, 2024, in the Japanese Patent Office, the entire contents of which are hereby incorporated by reference.

### BACKGROUND

### 1. Field

The present disclosure relates to an ejection apparatus, a substrate processing apparatus, a substrate processing method, a method of manufacturing a semiconductor device and a non-transitory computer-readable recording medium.

### 2. Related Art

In a method of manufacturing a semiconductor device, as an example of an apparatus capable of forming an oxide film or a metal film on a substrate, a vertical type substrate processing apparatus may be used. In the vertical type substrate processing apparatus, a boat is provided as a substrate retainer capable of supporting (or holding) a plurality of wafers in a multistage manner in a process vessel. The wafers (substrates) are processed by supplying a process gas to each of the substrates while the substrates are supported by the boat.

However, in such a method mentioned above, the process gas is supplied toward a center of each of the wafers. Thereby, a flow path area of the process gas may be reduced. In such a case, depending on a process, it may be difficult to sufficiently (or appropriately) control a flow of the process gas inside the process vessel.

### SUMMARY

According to the present disclosure, there is provided a technique capable of increasing a flow path area of a gas such as a process gas.

According to an embodiment of the present disclosure, there is provided a technique that includes: a first nozzle and a second nozzle facing a peripheral edge of a substrate and extending in a direction perpendicular to a main surface of the substrate, wherein each of the first and second nozzles is provided with: a front surface continuously formed on a side thereof facing the substrate; and a plurality of ejection holes arranged on the front surface in a direction parallel to the main surface of the substrate, wherein a gas is ejected through the plurality of ejection holes toward the substrate, and wherein, when a direction from a center of an arrangement of the first and second nozzles toward a center of the substrate is defined as a reference direction, the front surface of each of the first nozzle and the second nozzle is formed such that an angle of a normal to the front surface relative to the reference direction at positions where the plurality of ejection holes are located increases in an arrangement order of the plurality of ejection holes, and wherein, among the plurality of ejection holes of each of the first nozzle and the second nozzle, an ejection hole of the first nozzle closest to the second nozzle and an ejection hole of the second nozzle closest to the first nozzle are located on a substantially same tangent plane such that the gas is ejected from the first nozzle in a direction substantially parallel to the gas ejected from the second nozzle.

### BRIEF DESCRIPTION OF THE DRAWINGS

FIG. 1 is a diagram schematically illustrating a vertical cross-section of a substrate processing apparatus according to one or more embodiments of the present disclosure.

FIG. 2 is a diagram schematically illustrating a horizontal cross-section taken along a line A - A of the substrate processing apparatus shown in FIG. 1.

FIG. 3 is a diagram schematically illustrating a vertical cross-section taken along a line B - B of the substrate processing apparatus shown in FIG. 2.

FIG. 4 is a diagram schematically illustrating an enlarged cross-section of a part of the substrate processing apparatus shown in FIG. 3.

FIG. 5 is a diagram schematically illustrating a perspective view of an ejection apparatus according to the embodiments of the present disclosure.

FIG. 6 is a block diagram schematically illustrating a configuration of a controller and related components of the substrate processing apparatus according to the embodiments of the present disclosure.

FIG. 7 is a flow chart schematically illustrating a substrate processing according to the embodiments of the present disclosure.

FIG. 8 is a diagram schematically illustrating an enlarged cross-section of a part of a substrate processing apparatus according to a modified example of the present disclosure.

FIG. 9 is a diagram schematically illustrating a perspective view of an ejection apparatus according to the modified example of the present disclosure.

FIG. 10 is a diagram schematically illustrating a flow velocity distribution on a surface of a wafer when a nozzle according to the modified example of the present disclosure is provided.

### DETAILED DESCRIPTION

Hereinafter, one or more embodiments (also simply referred to as “embodiments”) of the technique of the present disclosure will be described with reference to the drawings.

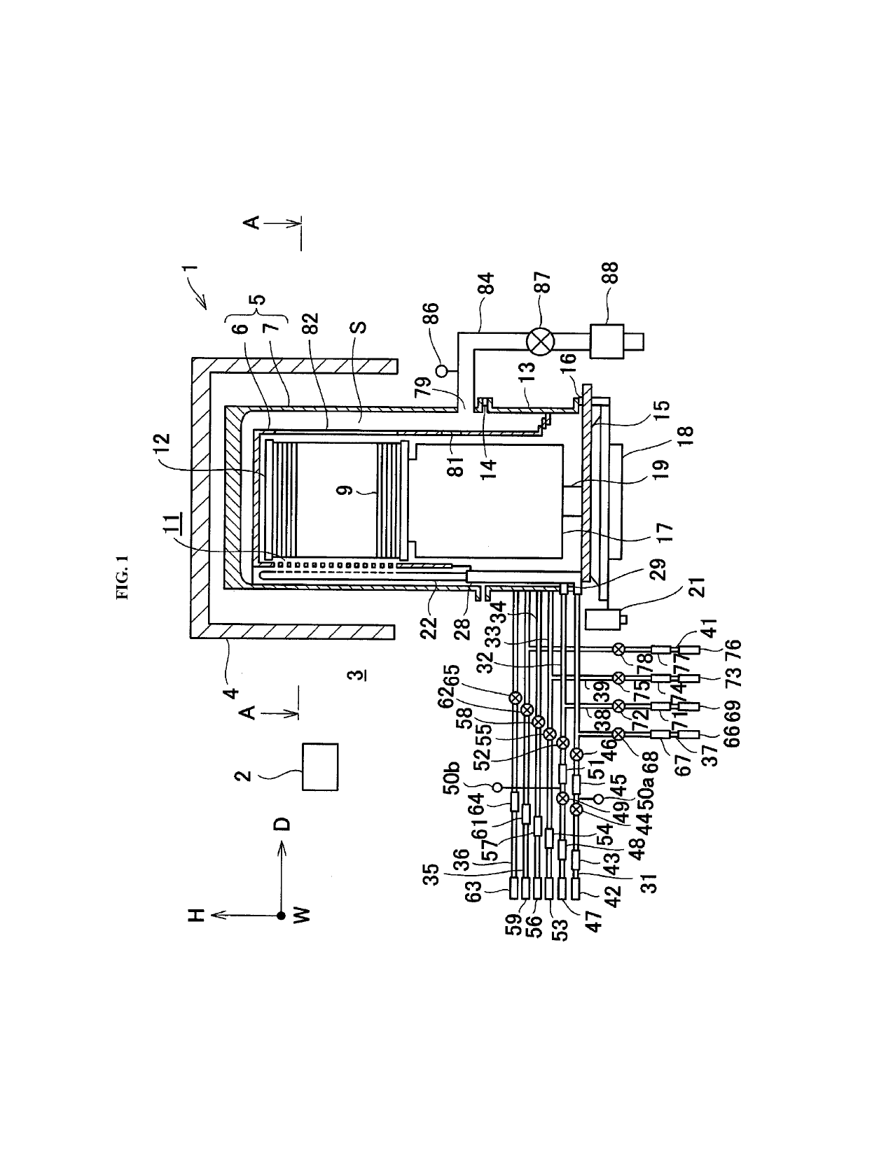

Hereinafter, the present embodiments will be described in detail mainly with reference to FIGS. 1 to 10. The drawings used in the following descriptions are all schematic. For example, a relationship between dimensions of each component and a ratio of each component shown in the drawing may not always match the actual ones. In addition, even between the drawings, the relationship between the dimensions of each component and the ratio of each component may not always match.

Further, the number of each component described in the present specification is not limited to one, and the number of each component may be two or more unless otherwise specified in the present specification. In addition, the same or similar reference numerals represent the same or similar components in the drawings. Thus, each component is described with reference to the drawing in which it first appears, and redundant descriptions related thereto will be omitted unless particularly necessary.

In the present specification, the term “wafer” may refer to “a wafer itself” or may refer to “a wafer and a stacked structure (aggregated structure) of a predetermined layer (or layers) or a film (or films) formed on a surface of the wafer”. In addition, in the present specification, the term “a surface of a wafer” may refer to “a surface of a wafer itself” or may refer to “a surface of a predetermined layer (or layers) or a film (or films) formed on a wafer”. Thus, in the present specification, the term “forming a predetermined layer (or a film) on a wafer” may refer to “forming a predetermined layer (or a film) on a surface of a wafer itself” or may refer to “forming a predetermined layer (or a film) on a surface of another layer (or another film) formed on a wafer”. In the present specification, the terms “substrate” and “wafer” may be used as substantially the same meaning.

In the present specification, the term “agent” may contain at least one selected from the group of a gaseous substance and a liquid substance. The liquid substance may contain a mist substance. That is, each of a film-forming agent, a modifying agent and an etching agent may contain a gaseous substance, may contain a liquid substance such as a mist substance, or may contain both of the gaseous substance and the liquid substance.

In the present specification, a notation of a numerical range such as “from 1 Pa to 2,000 Pa” means that a lower limit and an upper limit are included in the numerical range. Therefore, for example, a numerical range “from 1 Pa to 2,000 Pa” means a range equal to or higher than 1 Pa and equal to or less than 2,000 Pa. The same also applies to other numerical ranges described in the present specification. In addition, when a numerical range (which is related to a supply of a substance such as a gas) includes “0”, it refers to a case where the substance such as the gas is not supplied. For example, when a supply flow rate of the gas is zero (0) slm, it refers to a case where the gas is not supplied. The same also applies to the following descriptions.

### Overall Configuration of Substrate Processing Apparatus

First, an overall configuration of a substrate processing apparatus 1 according to the present embodiments will be described with reference to FIGS. 1 to 6. In the FIGS. 1 to 3, an up-down direction H of an apparatus (that is, the substrate processing apparatus 1) indicates a vertical direction, a width direction W of the apparatus indicates a horizontal direction, and a depth direction D of the apparatus indicates another horizontal direction.

As shown in FIG. 1, the substrate processing apparatus 1 according to the present embodiments includes a controller 2 and a process furnace 3. The controller 2 is configured to control components constituting the substrate processing apparatus 1. The process furnace 3 includes a heater 4 serving as a heating structure (heating apparatus). The heater 4 is of a cylindrical shape, and is installed in the up-down direction H of the apparatus while being supported by a heater base (not shown). The heater 4 also functions as an activator capable of activating a process gas by a heat. The controller 2 will be described in detail later.

A reaction tube 5 constituting a process vessel is vertically provided in an inner side of the heater 4 to be aligned in a manner concentric with the heater 4. The process vessel is configured such that a plurality of substrates can be accommodated therein. For example, the reaction tube 5 is made of a heat resistant material such as quartz (SiO₂) and silicon carbide (SiC). For example, the substrate processing apparatus 1 is a so-called “hot wall type substrate processing apparatus”.

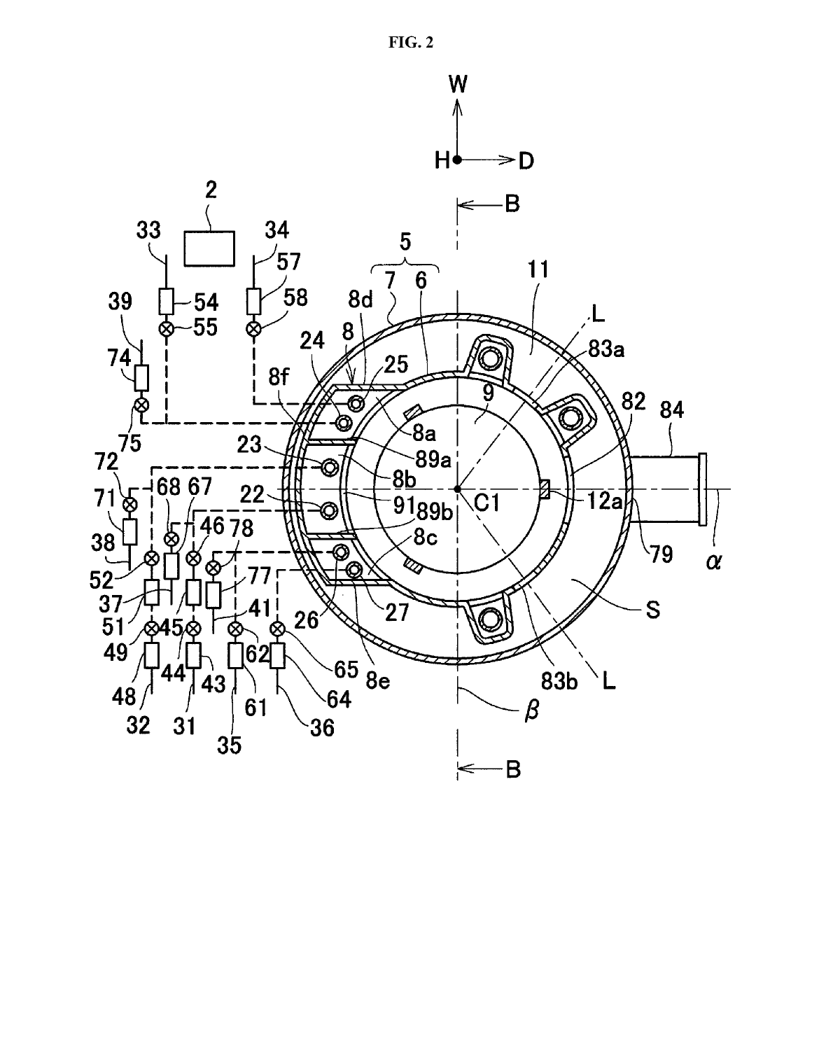

As shown in FIG. 2, the reaction tube 5 includes: an inner tube 6 of a cylindrical shape and an outer tube 7 of a cylindrical shape arranged to surround the inner tube 6. That is, the outer tube 7 constitutes the reaction tube 5 together with the inner tube 6. Since the outer tube 7 surrounds the inner tube 6, a gap serving as an exhaust space S is provided between cylinders (cylindrical portions) of the inner tube 6 and the outer tube 7. The inner tube 6 is provided in a manner concentric with the outer tube 7. The inner tube 6 serves as an example of a tube structure.

The inner tube 6 includes a side wall serving as the cylinder mentioned above. An upper portion of the side wall is covered by a ceiling. The cylinder of the inner tube 6 is configured such that that the plurality of substrates can be accommodated therein. Specifically, as shown in FIG. 1, the inner tube 6 is provided with an open lower end and a closed upper end (that is, the ceiling). The upper end of the inner tube 6 is closed by a flat wall body. In addition, the outer tube 7 is also provided with an open lower end and a closed upper end (that is, a ceiling). The upper end of the outer tube 7 is closed by a flat wall body. In addition, as shown in FIG. 2, a supply buffer 8 serving as a nozzle chamber is provided in the exhaust space S formed between the inner tube 6 and the outer tube 7. The supply buffer 8 will be described in detail later.

As shown in FIG. 1, a process chamber 11 is provided inside the inner tube 6 in a manner concentric with a plurality of wafers 9. The plurality of wafers 9 serving as the substrates are processed in the process chamber 11. Hereinafter, each of the wafers 9 may also be referred to as a “wafer 9”. The process chamber 11 is also configured such that a boat 12 serving as an example of a substrate retainer can be accommodated therein. The substrate retainer is configured such that the wafers 9 can be accommodated therein while arranged vertically in a multistage manner in a horizontal orientation with their centers aligned, and the inner tube 6 surrounds the wafers 9 accommodated in the boat 12. The wafers 9 are arranged inside the cylinder of the inner tube 6 along an axial direction of the cylinder of the inner tube 6. The inner tube 6 will be described in detail later.

A lower end of the reaction tube 5 (that is, the lower end of the inner tube 6 and/or the lower end of the outer tube 7) is supported by a manifold 13 of a cylindrical shape. For example, the manifold 13 is made of a metal such as a nickel alloy and stainless steel, or is made of a heat resistant material such as SiO₂ and SiC. A flange (not shown) is formed at an upper end of the manifold 13, and the lower end of the outer tube 7 is provided on the flange. An airtight seal 14 such as an O-ring is arranged between the flange and the lower end of the outer tube 7. Thereby, it is possible to maintain an inside (inner portion) of the reaction tube 5 airtight.

A seal cap 15 is airtightly attached (or provided) to an opening at a lower end of the manifold 13 via an airtight seal 16 such as an O-ring. Thereby, it is possible to maintain an opening at the lower end of the reaction tube 5 (that is, the opening at the lower end of the manifold 13) airtight. For example, the seal cap 15 is of a disk shape, and is made of a metal such as a nickel alloy and stainless steel. For example, the seal cap 15 may be configured such that an outside (outer portion) thereof is covered with a heat resistant material such as SiO₂ and SiC.

A boat support table (also referred to as a “boat support stand”) 17 configured to support the boat 12 is provided on the seal cap 15. For example, the boat support table 17 is made of a heat resistant material such as SiO₂ and SiC, and functions as a heat insulator.

The boat 12 is vertically provided on the boat support table 17. For example, the boat 12 is made of a heat resistant material such as SiO₂ and SiC. As shown in FIG. 1, the boat 12 includes: a bottom plate (not shown) fixed to the boat support table 17; a top plate (not shown) disposed above the bottom plate; and a plurality of support columns 12a (see FIG. 2) provided between the bottom plate and the top plate.

The boat 12 accommodates the wafers 9 to be processed in the process chamber 11 inside the inner tube 6. As shown in FIG. 1, the wafers 9 are supported by the support columns 12a of the boat 12 while arranged with a fixed interval (distance) therebetween and in a horizontal orientation with their centers aligned. A loading direction (stacking direction) of the wafers 9 is an axial direction of the reaction tube 5. In other words, the centers of the wafers 9 are aligned with a central axis of the boat 12. The central axis of the boat 12 coincides with a central axis of the reaction tube 5.

A rotator (which is a rotating structure) 18 configured to rotate the boat 12 is provided below the seal cap 15. A rotating shaft 19 of the rotator 18 is connected to the boat support table 17 by penetrating the seal cap 15. By rotating the boat 12 via the boat support table 17, the rotator 18 rotates the wafers 9.

The seal cap 15 is elevated and lowered in the vertical direction by an elevator 21 serving as an elevating structure provided outside the reaction tube 5. Thereby, the boat 12 can be transferred (loaded) into and transferred (unloaded) out of the process chamber 11.

A plurality of nozzle supports (nozzle support structures) (not shown) are provided in the manifold 13 so as to penetrate the manifold 13. For example, the nozzle supports are configured such that a plurality of nozzles through which gases are supplied into the process chamber 11 can be supported by the nozzle supports. For example, the nozzle supports are configured such that a nozzle 22 serving as a first nozzle, a nozzle 23 serving as a second nozzle, a nozzle 24 serving as a third nozzle, a nozzle 25 serving as a fourth nozzle, a nozzle 26 serving as a fifth nozzle and a nozzle 27 serving as a sixth nozzle can be supported by the nozzle supports. According to the present example, for example, the nozzle supports are provided corresponding to the nozzles. However, in FIG. 1, the nozzle 22 among the nozzles and a first nozzle support 28 and a second nozzle support 29 among the nozzle supports are illustrated. For example, each of the nozzle supports is made of a material such as a nickel alloy and stainless steel. Each of the nozzles 22 to 27 faces an end face (that is, a side face when a main surface, which is an upper surface or a primary surface, is facing up: also referred to as a “peripheral edge”) of the wafer 9 accommodated in the boat 12, and extends in a direction perpendicular to the main surface of the wafer 9.

Gas supply pipes 31, 32, 33, 34, 35 and 36 through which the gases are supplied into the process chamber 11 are connected to first ends (first end portions) of the nozzle supports, respectively. In addition, the nozzle 22, the nozzle 23, the nozzle 24, the nozzle 25, the nozzle 26 and the nozzle 27 are connected to second ends (second end portions) of the nozzle supports, respectively. In addition, a gas supply pipe 37 is connected to the gas supply pipe 31, a gas supply pipe 38 is connected to the gas supply pipe 32, a gas supply pipe 39 is connected to the gas supply pipe 33, and a gas supply pipe 41 is connected to the gas supply pipe 35. For example, each of the nozzles 22 to 27 is made of a heat resistant material such as SiO₂ and SiC. Each of the nozzles 22 to 27 will be described in detail later.

### Gas Supply Pipes

The gas supply pipes 31 and 37 are connected to an end (lower end) of the nozzle 22 via the first nozzle support 28, and fluidly communicate with the nozzle 22. The gas supply pipes 32 and 38 are connected to an end (lower end) of the nozzle 23 via the second nozzle support 29, and fluidly communicate with the nozzle 23. The gas supply pipes 33 and 39 are connected to the nozzle 24 via another nozzle support.

In addition, the gas supply pipe 34 is connected to the nozzle 25 via another nozzle support. The gas supply pipes 35 and 41 are connected to the nozzle 26 via another nozzle support. The gas supply pipe 36 is connected to the nozzle 27 via another nozzle support.

A source gas supply source 42 configured to supply a first source gas serving as one of process gases, a mass flow controller (also simply referred to as an “MFC”) 43 serving as an example of a flow rate controller, a valve 44 serving as an opening/closing valve, a tank 45 and a valve 46 are sequentially installed at the gas supply pipe 31 in this order from an upstream side to a downstream side of the gas supply pipe 31 in a gas flow direction. In addition, a source gas supply source 47 configured to supply the first source gas serving as one of the process gases, an MFC 48, a valve 49, a tank 51 and a valve 52 are sequentially installed at the gas supply pipe 32 in this order from an upstream side to a downstream side of the gas supply pipe 32 in the gas flow direction. Hereinafter, each of the process gases may also be referred to as the “process gas”.

The MFC 43 and the MFC 48 serve as a pair of flow rate controllers according to the present embodiments configured to supply the gas (that is, the first source gas) to a pair of tanks (that is, the tank 45 and the tank 51) at pre-set flow rates, respectively. The pre-set flow rates are set such that a reference accumulation amount serving as a target amount of the gas can be supplied. In addition, the valve 46 serves as an opening/closing valve configured to control a fluid communication of the gas between the nozzle 22 and the tank 45, and the valve 52 serves as an opening/closing valve configured to control a fluid communication of the gas between the nozzle 23 and the tank 51. The valve 46 and the valve 52 serve as a pair of opening/closing valves according to the present embodiments.

Further, when a flow rate of the gas cannot be limited to a pre-set flow rate, a control valve (not shown) provided inside each of the MFCs 43 and 48 is fully open or fully closed. Such a state may also be referred to as a “saturated state” or an “uncontrollable state”. According to the present embodiments, when the flow rate of the gas cannot be limited to the pre-set flow rate, the control valve inside each of the MFCs 43 and 48 may be fully open or fully closed, or may be in a state between fully open and fully closed.

Although not shown, each of the MFCs 43 and 48 is provided with an orifice and the control valve configured to control a pressure of the gas on a primary side of the orifice. Each of the MFCs 43 and 48 uses a choked flow of the orifice to control the flow rate of the gas.

The tanks 45 and 51 are configured to store the first source gas alone such that the first source gas supplied from the source gas supply sources 42 and 47 is not mixed with a carrier gas.

In addition, pressure sensors 50a and 50b are provided on upstream sides of the tanks 45 and 51, respectively. The pressure sensors 50a and 50b serve as a pair of pressure gauges (pressure meters) according to the present embodiments. The pressure sensors 50a and 50b are configured to measure pressures (inner pressures) of the tanks 45 and 51, respectively, while accumulating the gas.

A source gas supply source 53 configured to supply a second source gas serving as one of the process gases, an MFC 54 and a valve 55 are sequentially installed at the gas supply pipe 33 in this order from an upstream side to a downstream side of the gas supply pipe 33 in the gas flow direction. In addition, an assist gas supply source 56 configured to supply an assist gas serving as one of the process gases, an MFC 57 and a valve 58 are sequentially installed at the gas supply pipe 34 in this order from an upstream side to a downstream side of the gas supply pipe 34 in the gas flow direction. For example, the second source gas is also used as a reactive gas, and the assist gas is a gas different from both the first source gas and the second source gas.

A source gas supply source 59 configured to supply the second source gas serving as one of the process gases, an MFC 61 and a valve 62 are sequentially installed at the gas supply pipe 35 in this order from an upstream side to a downstream side of the gas supply pipe 35 in the gas flow direction. In addition, an assist gas supply source 63 configured to supply the assist gas serving as one of the process gases, an MFC 64 and a valve 65 are sequentially installed at the gas supply pipe 36 in this order from an upstream side to a downstream side of the gas supply pipe 36 in the gas flow direction.

The gas supply pipe 37 through which an inert gas is supplied is connected to the gas supply pipe 31 at a downstream side of the valve 46. An inert gas supply source 66 configured to supply the inert gas serving as one of the process gases, an MFC 67 and a valve 68 are sequentially installed at the gas supply pipe 37 in this order from an upstream side to a downstream side of the gas supply pipe 37 in the gas flow direction. The gas supply pipe 38 through which the inert gas is supplied is connected to the gas supply pipe 32 at a downstream side of the valve 52. An inert gas supply source 69 configured to supply the inert gas serving as one of the process gases, an MFC 71 and a valve 72 are sequentially installed at the gas supply pipe 38 in this order from an upstream side to a downstream side of the gas supply pipe 38 in the gas flow direction.

In addition, the gas supply pipe 39 through which the inert gas is supplied is connected to the gas supply pipe 33 at a downstream side of the valve 55. An inert gas supply source 73 configured to supply the inert gas serving as one of the process gases, an MFC 74 and a valve 75 are sequentially installed at the gas supply pipe 39 in this order from an upstream side to a downstream side of the gas supply pipe 39 in the gas flow direction. The gas supply pipe 41 through which the inert gas is supplied is connected to the gas supply pipe 35 at a downstream side of the valve 62. An inert gas supply source 76 configured to supply the inert gas serving as one of the process gases, an MFC 77 and a valve 78 are sequentially installed at the gas supply pipe 41 in this order from an upstream side to a downstream side of the gas supply pipe 41 in the gas flow direction. For example, the assist gas supply sources 56 and 63 and the inert gas supply sources 66, 69, 73 and 76 are connected to a common supply source.

### Supply System to Nozzle 22

A first source gas supply system (also referred to as a “first gas supplier”) configured to supply the first source gas to the nozzle 22 is constituted mainly by the gas supply pipe 31, the gas supply pipe 37, the MFC 43, the MFC 67, the tank 45, the valve 44, the valve 46 and the valve 68. The first source gas supply system configured to supply the first source gas to the nozzle 22 may further include the source gas supply source 42 and the inert gas supply source 66.

### Supply System to Nozzle 23

A first source gas supply system (also referred to as a “first gas supplier”) configured to supply the first source gas to the nozzle 23 is constituted mainly by the gas supply pipe 32, the gas supply pipe 38, the MFC 48, the MFC 71, the tank 51, the valve 49, the valve 52 and the valve 72. The first source gas supply system configured to supply the first source gas to the nozzle 23 may further include the source gas supply source 47 and the inert gas supply source 69.

### Supply System to Nozzle 24

A second source gas supply system (also referred to as a “second gas supplier”) configured to supply the second source gas to the nozzle 24 is constituted mainly by the gas supply pipe 33, the gas supply pipe 39, the MFC 54, the MFC 74, the valve 55 and the valve 75. The second source gas supply system configured to supply the second source gas to the nozzle 24 may further include the source gas supply source 53 and the inert gas supply source 73.

### Supply System to Nozzle 25

An assist gas supply system (also referred to as an “assist gas supplier”) configured to supply the assist gas only to an upper dummy region of two side dummy regions described later is constituted mainly by the gas supply pipe 34, the MFC 57 and the valve 58. The assist gas supply system configured to supply the assist gas to the upper dummy region alone may further include the assist gas supply source 56.

### Supply System to Nozzle 26

A second source gas supply system (also referred to as a “second gas supplier”) configured to supply the second source gas to the nozzle 26 is constituted mainly by the gas supply pipe 35, the gas supply pipe 41, the MFC 61, the MFC 77, the valve 62 and the valve 78. The second source gas supply system configured to supply the second source gas to the nozzle 26 may further include the source gas supply source 59 and the inert gas supply source 76.

### Supply System to Nozzle 27

An assist gas supply system (also referred to as an “assist gas supplier”) configured to supply the assist gas only to a lower dummy region of the two side dummy regions described later is constituted mainly by the gas supply pipe 36, the MFC 64, and the valve 65. The assist gas supply system configured to supply the assist gas to the lower dummy region alone may further include the assist gas supply source 63.

### Tanks

The tanks 45 and 51 are configured such that volumes thereof are substantially the same. The tanks 45 and 51 can store the source gas alone so that the source gas is not mixed with the carrier gas. The tanks 45 and 51 are configured to substantially (approximately) simultaneously supply the source gas stored therein to the nozzles 22 and 23 through the opening/closing valves, respectively, in a pulse manner. The tanks 45 and 51 serve as a pair of tanks according to the present embodiments. The inner pressure of each of the tanks 45 and 51 is usually below an atmospheric pressure. The inner pressure of each of the tanks 45 and 51 may vary depending on a vapor pressure of the source gas. As the tanks 45 and 51, an isothermal tank, which is filled with a substance such as a metal wool and a filament and heated by an electric heater, may be used.

That is, according to the present embodiments, it is possible to perform a flash supply of the source gas whose concentration is high. In such a flash supply, the source gas stored in the tanks 45 and 51 is supplied at a high flow rate from the tanks 45 and 51 toward the reaction tube 5 via the nozzles 22 and 23 in a short period of time. The source gas supplied at a high flow rate using the tanks 45 and 51 may also be referred to as the “source gas supplied in a flash flow manner”. During a film forming process, the source gas supplied in the flash flow manner is diffused with a low degree of decomposition over a surface of the wafer 9 inside the cylinder of the inner tube 6.

By supplying the source gas in the flash flow manner, during the film forming process, the entire surface of the wafer 9 is exposed to the source gas whose partial pressure is high. A method using a temporary increase in the pressure in such a manner is one of the most effective methods to promote a push of the gas into a fine structure such as a trench and a hole formed on the surface of the wafer 9, and is particularly useful in processing a patterned wafer with a high aspect ratio.

In addition, the present embodiments are not limited to the flash supply of the source gas (that is, a supply of the source gas in the flash flow manner). For example, the present embodiments may also be applied to a supply of a substance (such as the inert gas serving as a purge gas) at a large flow rate using a general MFC.

### Exhaust system

A main exhaust port (also referred to as a “primary exhaust port”) 79 is provided at the outer tube 7 of the reaction tube 5. The main exhaust port 79 is provided below an exhaust port 81 of the inner tube 6. A main exhaust slit (also referred to as a “primary exhaust slit”) 82 serving as an exhaust structure is provided at the inner tube 6 of the reaction tube 5. In other words, the reaction tube 5 is provided with the main exhaust slit 82 on a side surface thereof.

As shown in FIG. 2, the main exhaust port 79 is arranged so as to be aligned on the same straight line as the main exhaust slit 82 when viewed from above. As shown in FIG. 2, two subsidiary exhaust slits 83a and 83b are arranged symmetrically with respect to the line passing through the main exhaust port 79 and the main exhaust slit 82 when viewed from above. The subsidiary exhaust slits 83a and 83b correspond to a subsidiary exhaust structure of the present embodiments.

The main exhaust port 79 is configured to communicate between the exhaust space S and an outside (outer portion) of the reaction tube 5. The main exhaust port 79 corresponds to an exhaust port of the present embodiments. An exhaust duct 84 through which the source gas is sent to the outside of the reaction tube 5 is connected to the main exhaust port 79.

A vacuum pump 88 serving as an exhaust apparatus is connected to the exhaust duct 84 via a pressure sensor 86 and an APC (Automatic Pressure Controller) valve 87. The pressure sensor 86 is configured to detect a pressure (inner pressure) of the process chamber 11, and the APC (Auto Pressure Controller) valve 87 serves as a pressure regulator (which is a pressure adjusting structure). The exhaust duct 84 downstream of the vacuum pump 88 is connected to a component such as a waste gas treatment apparatus (not shown). With such a configuration, by controlling an output of the vacuum pump 88 and an opening degree of the APC valve 87, it is possible to vacuum-exhaust the process chamber 11 such that the inner pressure of the process chamber 11 can be adjusted (or set) to a predetermined pressure (that is, a vacuum degree).

A main exhaust system (also referred to as a “primary exhaust system”, a “main exhauster” or a “primary exhauster”) is constituted mainly by the exhaust duct 84, the APC valve 87 and the pressure sensor 86. The main exhaust system may further include the vacuum pump 88.

In addition, a temperature sensor (not shown) serving as a temperature detector is provided in the reaction tube 5. By adjusting a power supplied (applied) to the heater 4 based on temperature information detected by the temperature sensor, it is possible to set (or adjust) a distribution of a temperature (inner temperature) of the process chamber 11 to a desired temperature distribution.

With such a configuration, in the process furnace 3, the boat 12 supporting the wafers 9 (which are to be batch processed) in a multistage manner is transferred (loaded) into the process chamber 11 by the boat support table 17. The wafers 9 loaded into the process chamber 11 are then heated to a predetermined temperature by the heater 4. An apparatus provided with such a process furnace may also be referred to as a “vertical type batch apparatus”. The wafers 9 accommodated in the process chamber 11 can be broadly classified into product wafers and side dummy wafers. Each of the product wafers is a wafer on which a semiconductor device such as an IC (integrated circuit) is actually manufactured. The product wafers are placed in a center portion (in the up-down direction) of the entire arrangement region of the wafers 9 arranged in the process chamber 11. On the other hand, the side dummy wafers are wafers used instead of the product wafers, and are placed in positions, among the entire arrangement region of the wafers 9 arranged in the process chamber 11, where a quality of wafers serving as the product wafers cannot be ensured, for example, at both ends in the vertical direction. That is, the side dummy wafers are placed with a product region interposed therebetween. In the process chamber 11, a region in which the product wafers are placed may also be referred to as the “product region”, and a region in which the side dummy wafers are placed may also be referred to as a “dummy region”. Hereinafter, the side dummy wafers may also be referred to as “dummy wafers”.

As shown in FIG. 2, the supply buffer 8 is a region provided on the side wall of the cylinder of the inner tube 6 and protrudes radially outward from the side wall. The supply buffer 8 is formed (or defined) by side walls 8d and 8e protruding radially outward and a peripheral wall 8f formed along an inner surface of the outer tube 7 (that is, an inner surface of the process chamber 11). The supply buffer 8 may be divided into three portions 8a, 8b and 8c along a circumferential direction of the cylinder by partitions 89a and 89b. In addition, each of the divided portions 8a, 8b and 8c (that is, a left portion 8a, a central portion 8b and a right portion 8c) of the supply buffer 8 may be used as nozzle chambers. Each of the partitions 89a and 89b functions as a gas guide plate configured to prevent a vortex from occurring within the supply buffer 8 and to prevent a backflow into the supply buffer 8.

Among the divided portions 8a, 8b and 8c of the supply buffer 8, the nozzles 22 and 23 through the first source gas is supplied are provided in the central portion 8b surrounded by the partitions 89a and 89b and the peripheral wall 8f. For example, a width of the central portion 8b is set to be within a range from 1 to 1.2 times a sum of lateral widths of the nozzles 22 and 23. Thereby, it is possible to reduce a dead space in the central portion 8b and to increase a flow path area of each of the nozzles 22 and 23. As a result, it is possible to suppress a backflow of the first source gas. At a boundary between the central portion 8b of the supply buffer 8 and the cylinder, a sector (that is, a sector of a fan shape) is formed by a virtual arc connecting both circumferential ends of the cylinder, and a center C1 of the wafer 9. According to the present embodiments, a central angle of the sector is set to be less than 30°. According to the present embodiments, the central angle of the sector can be set arbitrarily. In addition, a direction from a center of an arrangement of the nozzles 22 and 23 toward the center C1 of the wafer 9 may be defined as a “reference direction A”.

An ejection apparatus capable of ejecting the first source gas onto the wafers 9 is constituted by at least the nozzles 22 and 23. The ejection apparatus may further include other nozzles 24 to 27, and may further include the nozzle supports 28 and 29. The ejection apparatus may further include the gas supply systems mentioned above.

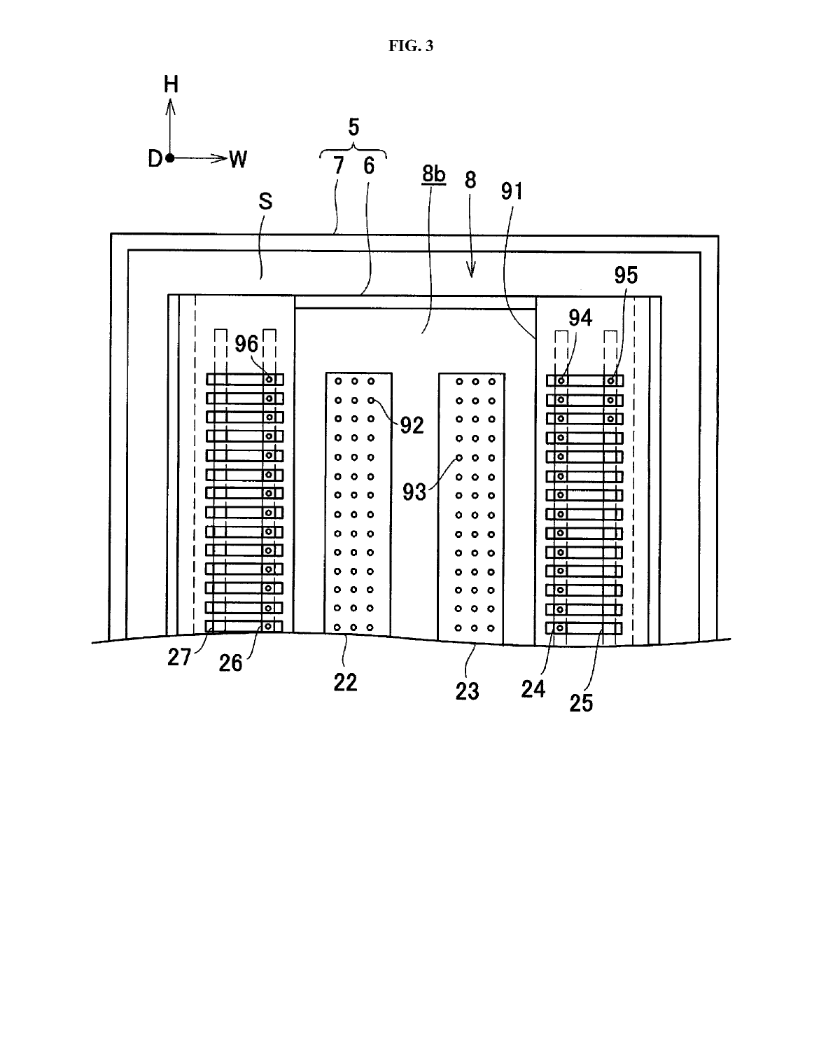

As shown in FIG. 3, a supply slit 91 is provided at the central portion 8b of the supply buffer 8. The supply slit 91 opens over the entirety of the central portion 8b across at least the product region (product wafer region) in the up-down direction H of the apparatus, and over the entire width of the central portion 8b itself in the width direction W of the apparatus. Therefore, a plurality of ejection holes 92 of the nozzle 22 and a plurality of ejection holes 93 of the nozzle 23, which are configured to supply the gas directly to the wafers 9, face the wafers 9 exposed inside the cylinder throughout both in the up-down direction H of the apparatus and in the width direction W of the apparatus. In addition, a supply slit 90 is provided for each of the wafers 9 in the left portion 8a and the right portion 8c of the supply buffer 8.

### Exhaust Slits

As shown in FIG. 2, a plurality of exhaust slits (which include the main exhaust slit 82 and the subsidiary exhaust slits 83a and 83b) are provided at the side wall of the cylinder. The exhaust slits are configured such that the source gas is exhausted from inside the cylinder. According to the present embodiments, the number of the exhaust slits is three (that is, one main exhaust slit 82 and two subsidiary exhaust slits 83a and 83b). According to the present embodiments, the number of the exhaust slits may preferably be two or more.

### Main Exhaust Slit

The main exhaust slit 82 is provided at the side wall of the cylinder opposite to the supply buffer 8 with respect to the center C1 of the wafer 9.

### Subsidiary Exhaust Slits

The two subsidiary exhaust slits 83a and 83b are open on both sides of an imaginary vertical plane α set inside the cylinder. The imaginary vertical plane α is a plane perpendicular to the wafer 9. As shown in FIG. 2, the imaginary vertical plane α is set so as to, when viewed from above, pass through a circumferential center of the cylinder at a boundary between the supply buffer 8 and the cylinder and an axis of the cylinder (that is, the center C1 of the wafer 9). The axis of the cylinder overlaps with the center C1 of the wafer 9.

The two subsidiary exhaust slits 83a and 83b serving as a pair of exhaust slits are provided at the same height as the main exhaust slit 82 with the main exhaust slit 82 interposed therebetween. When viewed from above, imaginary lines L (which connect each of centers of the subsidiary exhaust slits 83a and 83b and the center C1 of the wafer 9) are set. According to the present embodiments, an angle between each of the imaginary lines L and the imaginary vertical plane α is an obtuse angle. Such an angle mentioned above is measured starting from the supply buffer 8. According to the present embodiments, the angle between each of the imaginary lines L and the imaginary vertical plane α is not limited to an obtuse angle.

As shown in FIG. 2, a width of each of the two subsidiary exhaust slits 83a and 83b along the circumferential direction of the cylinder is smaller than a width of the main exhaust slit 82. However, according to the present embodiments, the width of each of the subsidiary exhaust slits 83a and 83b may be greater than or equal to the width of the main exhaust slit 82.

According to the present embodiments, an opening width of the main exhaust slit 82 along the circumferential direction of the cylinder may be narrowed from an upper portion (top) to a lower portion (bottom) along the axial direction of the cylinder. Similarly, an opening width of each of the pair of subsidiary exhaust slits 83a and 83b along the circumferential direction of the cylinder may be narrowed from top to bottom along the axial direction of the cylinder. According to the present embodiments, the opening widths of each of the main exhaust slit 82 and the pair of subsidiary exhaust slits 83a and 83b along the circumferential direction of the cylinder may be set appropriately.

In addition, the subsidiary exhaust slits 83a and 83b are located opposite to the supply buffer 8 with an imaginary plane β interposed therebetween, and are configured such that the gas supplied from the supply buffer 8 is exhausted to an outside (outer portion) of the cylinder at a position farther than the imaginary plane β. Thereby, it is possible to sufficiently circulate (supply) the gas supplied into the process chamber 11 within the process chamber 11. According to the present embodiments, the imaginary plane β is a plane perpendicular to the wafer 9. As shown in FIG.2, the imaginary plane β is set to pass through the axis of the cylinder (the center C1 of the wafer 9) when viewed from above, and to separate the supply buffer 8 from the main exhaust slit 82 and the subsidiary exhaust slits 83a and 83b.

### Main Configuration

Subsequently, each of the nozzles in the substrate processing apparatus 1 according to the present embodiments will be described in detail. In addition, positions of the nozzles 22, 23, 24, 25, 26 and 27 in FIG. 3 are schematically illustrated for explanation, and may differ from the actual positions thereof inside the process chamber 11. In addition, in the following descriptions, the position of each of the nozzles when viewed from above may refer to a center position of each nozzle of a cylindrical shape.

In the supply buffer 8, the nozzle 22 serving as a first ejector, the nozzle 23 serving as a second ejector, the nozzle 24 serving as a third ejector, the nozzle 25 serving as a fourth ejector, the nozzle 26 serving as a fifth ejector and the nozzle 27 serving as a sixth ejector are arranged. In addition, among the divided portions 8a, 8b and 8c of the supply buffer 8, the nozzles 22 and 23 are located in the central portion 8b, the nozzle 24 and the nozzle 25 are located in the left portion 8a (that is, a portion surrounded by the side wall 8d, the peripheral wall 8f and the partition 89a) on a left side of the gas flow direction from the supply buffer 8 to the main exhaust slit 82, and the nozzle 26 and the nozzle 27 are located in the right portion 8c (that is, a portion surrounded by the partition 89b, the peripheral wall 8f and side wall 8e) on a right side of the gas flow direction from the supply buffer 8 to the main exhaust slit 82. In addition, the nozzles 22 and 23 are configured to be arranged symmetrically with respect to the imaginary vertical plane α. As a result, it is possible to uniformly (or evenly) supply the first source gas through the nozzles 22 and 23 to the process chamber 11. In other words, the ejection apparatus configured to eject (or supply) the first source gas to the process chamber 11 is constituted by the nozzles 22 and 23.

### First Ejector

The nozzle 22 extends in the up-down direction, and is disposed opposite the main exhaust slit 82 as shown in FIG. 2. In addition, the nozzle 22 is supported by the first nozzle support 28. For example, the nozzle 22 is constituted by: an end structure (end portion) 22c connected to the gas supply pipe 31; a transition structure (transition portion) 22a whose cross-sectional area gradually increases from a lower end (bottom) to an upper end (top) thereof and whose cross-sectional shape changes along a direction in which the first source gas flows; and a cylinder (which is a cylindrical structure or a cylindrical portion) 22b extending upward from the upper end of the transition structure 22a. For example, a cross-sectional shape of the cylinder 22b is set to be uniform over the entire length thereof in the up-down direction.

The transition structure 22a is configured to connect the end structure 22c to the cylinder 22b. In addition, the cylinder 22b is provided with a front surface 22d formed continuously on its side facing the wafers 9. The front surface 22d is a curved surface whose curvature is opposite to that of the inner tube 6 with respect to an imaginary plane γ (which is located between the front surface 22d and the supply slit 91, and is parallel to the imaginary plane β). The front surface 22d is curved so as to gradually move away from the supply slit 91 as it goes from a center of the central portion 8b toward the partition 89b.

In addition, the cylinder 22b is provided with: a side surface 22e extending radially outward from a central end of the front surface 22d and parallel or substantially parallel to a radial direction from the center of the wafer 9; a back surface (rear surface) 22f provided (formed) between an outer peripheral end of the side surface 22e and an end of the front surface 22d facing the partition 89b. Therefore, the side surface 22e faces an opposing nozzle (that is, the nozzle 23), and the cylinder 22b is provided with a roughly triangular cross-section. A thickness of the cylinder 22b gradually decreases from the center of the central portion 8b toward the partition 89b.

In the present specification, the term “substantially parallel” or “substantially the same tangential plane” means that a normal (normal line) or a spray direction of the nozzle 22 or 23 related thereto is within ± 5° with respect to a reference direction related thereto. In addition, the back surface 22f may be a cylindrical surface along an inner surface of the process chamber 11 or the peripheral wall 8f, or may be a planar surface formed in a similar manner as the cylindrical surface. The same applies to a back surface 23f described later. With such a configuration, it is possible to increase a cross-sectional area (flow path area) of the cylinder of each of the nozzles 22 and 23.

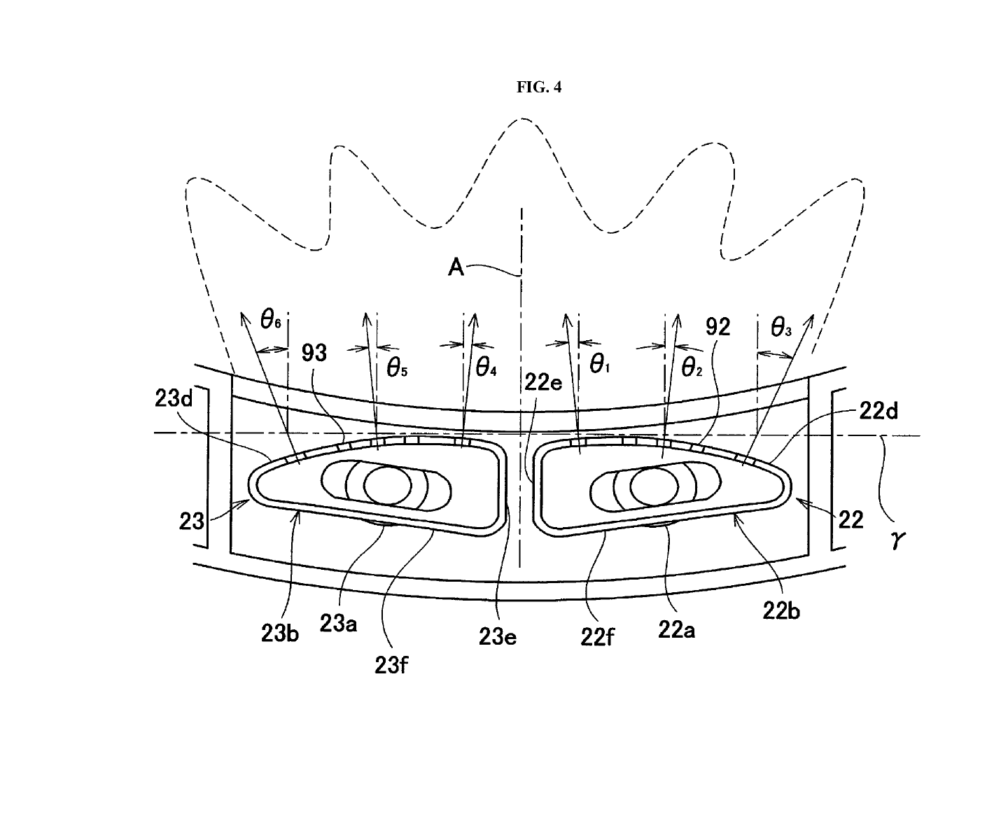

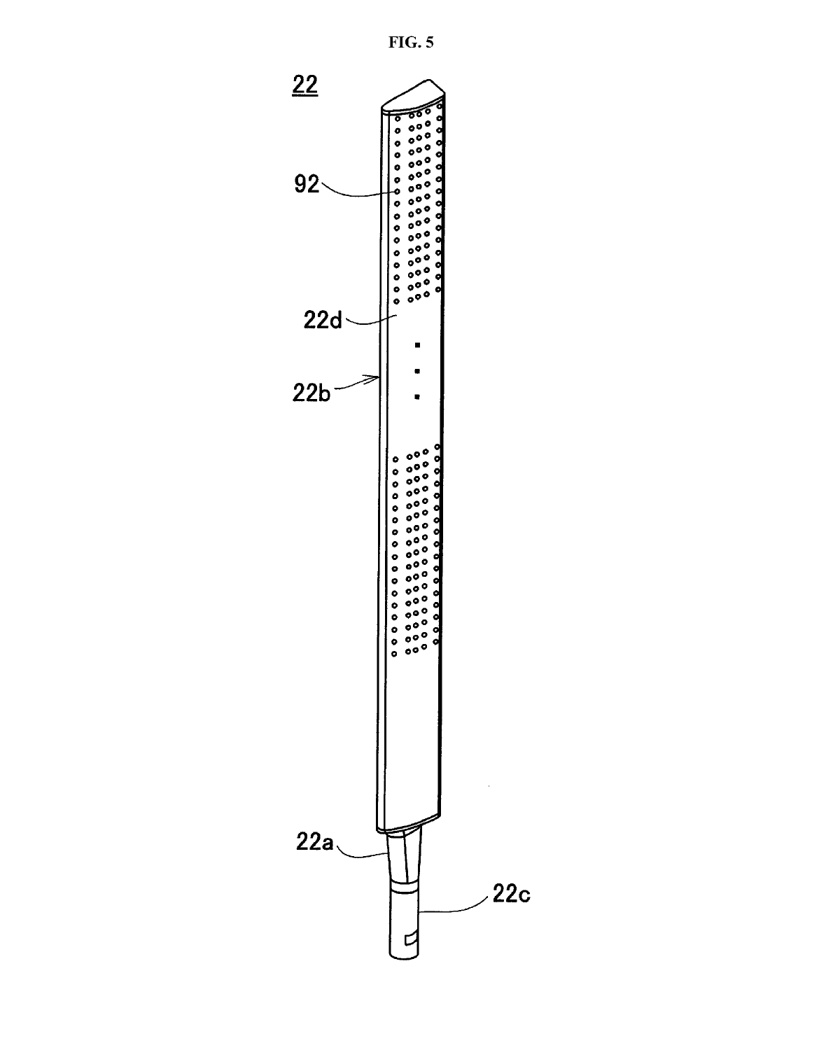

As shown in FIGS. 4 and 5, the front surface 22d is provided with the plurality of ejection holes 92 arranged in a direction parallel to the main surface of the wafer 9. The gas is ejected through the ejection holes 92 toward the wafers 9. The ejection holes 92 are formed in the front surface 22d along a direction substantially perpendicular to a thickness direction. According to the present embodiments, for example, five ejection holes 92 are provided. The ejection holes 92 are provided at a predetermined interval. In addition, the curvature of the front surface 22d is set such that an angle of each normal to the front surface 22d relative to the reference direction A at positions where the ejection holes 92 are arranged monotonically increases in an arrangement order of the ejection holes 92. The angle is defined to be positive in a direction away from the imaginary vertical plane α. That is, when an inclination angle of a main stream line (normal) of a centermost ejection hole (among the ejection holes 92) with respect to the reference direction A is defined as θ₁, an inclination angle of a main stream line (normal) of an ejection hole (among the ejection holes 92) closest to the partition 89b with respect to the reference direction A is defined as θ₃ and an inclination angle of a main stream line (normal) of an ejection hole (among the ejection holes 92) other than those at the ends with respect to the reference direction A is defined as θ₂, a relationship between the inclination angles is “θ₁ < θ₂ < θ₃”, that is, θ₁ is less than θ₂, and θ₂ is less than θ₃. In addition, the main stream line of the centermost ejection hole 92 is substantially parallel to the reference direction A, and θ₁ is ± 5°. Therefore, the front surface 22d is a convex surface curved toward the wafer 9 over the entire area where the ejection holes 92 are arranged, and is configured such that a distance from the wafer 9 increases as it moves farther away from the opposing nozzle (that is, the nozzle 23). Therefore, simply by forming a plurality of perpendicular holes on the front surface 22d, it is possible to obtain the plurality of ejection holes 92 whose angles with respect to the reference direction A monotonically increase.

In addition, the ejection holes 92 are not limited to such a configuration arranged in a straight line perfectly parallel to the main surface of the wafer 9. For example, it is sufficient as long as the ejection holes 92 are aligned along the main surface of the wafer 9 as a whole. Accordingly, an arrangement of the ejection holes 92 in the direction parallel to the main surface of the wafer 9 may include an arrangement in which the ejection holes 92 are zigzagged in the up-down direction, or may include an arrangement in which the ejection holes 92 are inclined (tilted) within ± 5° from the direction parallel to the main surface of the wafer 9. In addition, the term “monotonically increase” may also refer to a case in which the inclination angles of some (but not all) consecutive ejection holes 92 are the same.

At least one among the ejection holes 92 may directly face the main exhaust slit 82 with a central axis of the wafer 9 therebetween. In addition, the other ejection holes (among the ejection holes 92) are inclined at a predetermined angle with respect to the reference direction, and are configured such that the gas is ejected through the other ejection holes in a direction inclined relative to an ejection direction of the ejection hole (among the ejection holes 92) directly facing the main exhaust slit 82. Therefore, the first source gas is ejected radially through the ejection holes 92 when viewed from above.

### Second Ejector

The nozzle 23 is provided as a mirror image of the nozzle 22, and is supported by the second nozzle support 29. For example, the nozzle 23 is constituted by: an end structure (end portion) (not shown, however, also referred to as an end structure 23c) connected to the gas supply pipe 32; a transition structure (transition portion) 23a whose cross-sectional area gradually increases from a lower end (bottom) to an upper end (top) thereof and whose cross-sectional shape changes along a direction in which the first source gas flows; and a cylinder (which is a cylindrical structure or a cylindrical portion) 23b extending upward from the upper end of the transition structure 23a. For example, a cross-sectional shape of the cylinder 23b is set to be uniform over the entire length thereof in the up-down direction.

The transition structure 23a is configured to connect the end structure 23c to the cylinder 23b. In addition, the cylinder 23b is provided with a front surface 23d formed continuously on its side facing the wafers 9. The front surface 23d is a curved surface whose curvature is opposite to that of the inner tube 6 with respect to the imaginary plane γ. The front surface 23d is curved so as to gradually move away from the supply slit 91 as it goes from the center of the central portion 8b toward the partition 89a. In addition, the cylinder 23b is provided with: a side surface 23e extending radially outward from a central end of the front surface 23d and parallel or substantially parallel to the radial direction from the center of the wafer 9; a back surface (rear surface) 23f provided (formed) between an outer peripheral end of the side surface 23e and an end of the front surface 23d facing the partition 89a. Therefore, the side surface 23e faces an opposing nozzle (that is, the nozzle 22), and the cylinder 23b is provided with a roughly triangular cross-section. A thickness of the cylinder 23b gradually decreases from the center of the central portion 8b toward the partition 89a.

The front surface 23d is provided with the plurality of ejection holes 93 arranged in a direction parallel to the main surface of the wafer 9. The gas is ejected through the ejection holes 93 toward the wafers 9. The ejection holes 93 are formed in the front surface 23d along a direction substantially perpendicular to a thickness direction. According to the present embodiments, for example, five ejection holes 93 are provided. The ejection holes 93 are provided at a predetermined interval. In addition, the curvature of the front surface 23d is set such that an angle of each normal to the front surface 23d relative to the reference direction A at positions where the ejection holes 93 are arranged monotonically increases in an arrangement order of the ejection holes 93. That is, when an inclination angle of a main stream line (normal) of a centermost ejection hole (among the ejection holes 93) with respect to the reference direction A is defined as θ₄, an inclination angle of a main stream line (normal) of an ejection hole (among the ejection holes 93) closest to the partition 89a with respect to the reference direction A is defined as θ₆ and an inclination angle of a main stream line (normal) of an ejection hole (among the ejection holes 93) other than those at the ends with respect to the reference direction A is defined as θ₅, a relationship between the inclination angles is “θ₄ < θ₅ < θ₆”, that is, θ₄ is less than θ₅, and θ₅ is less than θ₆. In addition, the main stream line of the centermost ejection hole 93 is substantially parallel to the reference direction A, and θ₄ is ± 5° with respect to the reference direction A. Therefore, the front surface 23d is a convex surface curved toward the wafer 9 over the entire area where the ejection holes 93 are arranged, and is configured such that a distance from the wafer 9 increases as it moves farther away from the opposing nozzle (that is, the nozzle 22). Therefore, simply by forming a plurality of perpendicular holes on the front surface 23d, it is possible to obtain the plurality of ejection holes 93 whose angles with respect to the reference direction A monotonically increase.

At least one among the ejection holes 93 may directly face the main exhaust slit 82 with the central axis of the wafer 9 therebetween. In addition, the other ejection holes (among the ejection holes 93) are inclined in a direction opposite to that of the ejection holes 93 at a predetermined angle with respect to the reference direction, and are configured such that the gas is ejected through the other ejection holes in a direction inclined relative to an ejection direction of the ejection hole (among the ejection holes 93) directly facing the main exhaust slit 82. Therefore, the first source gas is ejected radially through the ejection holes 93 when viewed from above.

In addition, the nozzles 22 and 23 are arranged such that the side surface 23e is adjacent and is parallel or substantially parallel to the side surface 22e. Further, since the nozzles 22 and 23 are mirror-symmetrical, θ₁ = θ₄ or θ₁ ≈ θ₄, θ₂ = θ₅ or θ₂ ≈ θ₅, and θ₃ = θ₆ or θ₃ ≈ θ₆, that is, θ₁ is equal to or substantially equal to θ₄, θ₂ is equal to or substantially equal to θ₅, and θ₃ is equal to or substantially equal to θ₆. In such a state, the main stream lines of the centermost ejection holes (that is, the ejection hole among the ejection holes 92 of the nozzle 22 and the ejection hole among the ejection holes 93 of the nozzle 23 closest to each opposing nozzle) are substantially parallel to the reference direction A, and the ejection hole of the nozzle 22 and the ejection hole of the nozzle 23 closest to each opposing nozzle are formed on substantially the same tangent plane such that the first source gas from the nozzle 22 and the first source gas from the nozzle 23 can be ejected substantially parallel to each other. Thereby, since an installation space for the nozzles 22 and 23 can be reduced and the gases ejected through the ejection hole of the nozzle 22 and the ejection hole of the nozzle 23 closest to each opposing nozzle can be joined together (merged), their main stream lines can be considered to be the same.

As described above, according to the present embodiments, the ejection holes 92 of the nozzle 22 and the ejection holes 93 of the nozzle 23 are configured such that the first source gas is ejected in directions opposed to each other, roughly in a direction of five main stream lines. In FIG. 4, an example of a uniform flow velocity line of the first source gas is shown by a dashed line.

According to the present embodiments, opening areas of ejection holes (among the ejection holes 92) located at both ends are set to be greater than opening areas of adjacent ejection holes (among the ejection holes 92). Therefore, it is possible to increase a flow rate of the first source gas ejected through the ejection holes (among the ejection holes 92) at both ends. In addition, a diameter of at least one of the ejection holes 92 is set to be greater than a thickness of the front surface 22d. Therefore, it is possible to reduce an internal nozzle pressure (that is, an inner pressure of a nozzle related thereto) appropriately to obtain a desired flow rate, and it is also possible to suppress a decomposition within the nozzle. In addition, according to the present embodiments, a set (or sets) of the ejection holes 92 (which are arranged in a direction parallel to the main surfaces of the wafers 9) is (or are) provided in a multistage manner corresponding to the substrates (including the wafers 9) arranged in a direction perpendicular to the wafer 9, and a height of each of the ejection holes 92 corresponds to each of the wafers 9 arranged in a multistage manner. As a result, it is possible to efficiently supply the first source gas to each of the wafers 9. In addition, a distance between a boundary (between the cylinder 22b and the transition structure 22a) and each of the ejection holes 92 is set to be greater than the Kolmogorov length.

Such a configuration and operation mentioned above may also be applied to the ejection holes 93 of the nozzle 23.

In addition, among the ejection holes 92 of the nozzle 22 and the ejection holes 93 of the nozzle 23, a distance (spacing) between the ejection hole of the nozzle 22 closest to the nozzle 23 and the ejection hole of the nozzle 23 closest to the nozzle 22 is set to be equal to or greater than the narrowest spacing between the ejection holes 92 of the nozzle 22 and equal to or less than twice the widest spacing between the ejection holes 92 of the nozzle 22, and set to be equal to or greater than the narrowest spacing between the ejection holes 93 of the nozzle 23 and equal to or less than twice the widest spacing between the ejection holes 93 of the nozzle 23. In other words, a difference in the spacing of the ejection holes is reduced throughout the entirety of the ejection apparatus. On the other hand, when the ejection holes of the nozzle are too close together, the flows of the gases may join together. As a result, a wide radial flow may not be obtained. In addition, when the ejection holes of the nozzle are too far apart, the vortex may occur, and it may take longer for the gas to reach the substrate (that is, the wafer 9). As a result, the decomposition of the gas may be accelerated.

In addition, when the ejection holes 92 (and/or the ejection holes 93) are formed obliquely with respect to the thickness direction of the nozzle 22 (and/or the thickness direction of the nozzle 23), since the flow rate of the gas in the vicinity of an outlet of the ejection holes 92 (and/or the flow rate of the gas in the vicinity of an outlet the ejection holes 93) is different between a location (side) closer to the opposing nozzle and a location (side) farther away from the opposing nozzle, a difference in a conductance thereof may occur. When such a difference in the conductance occurs, the first source gas is deflected toward a location (side) with a lower conductance (the location closer to the opposing nozzle), and a main stream line is formed in substantially the same direction as a desired thickness direction. As a result, the first source gas may not flow. According to the present embodiments, by forming (providing) the ejection holes 92 and the ejection holes 93 along a direction substantially perpendicular to the thickness directions of the nozzles 22 and 23, it is possible to uniformize the conductance in the vicinity of the outlet of the ejection holes 92 and the outlet of the ejection holes 93. Therefore, the first source gas ejected through the ejection holes 92 and the ejection holes 93 can be strongly directed in the direction substantially perpendicular to the thickness directions of the nozzles 22 and 23.

### Third Ejector

The nozzle 24 is provided with a plurality of ejection holes 94 facing at least the product region of the process chamber 11. The nozzle 24 is configured such that the second source gas is supplied to the product wafers and the dummy wafers through the ejection holes 94. For example, the ejection holes 94 may be provided in both the product region and the dummy region, or may be provided in the product region alone.

### Fourth Ejector

The nozzle 25 is provided with one or more ejection holes 95 through which the assist gas is supplied only to the substrates (wafers 9) in the upper dummy region (that is, an upper portion of the dummy region) of the dummy region. As described above, the number of the ejection holes 95 at the nozzle 25 is one or more. In other words, the nozzle 25 is configured such that the assist gas is supplied to one or more stages of the dummy wafers. While the present embodiments will be described by way of an example in which the number of the one or more ejection holes 95 at the nozzle 25 is three, the present embodiments are not limited thereto. For example, according to the present embodiments, the number of the one or more ejection holes 95 may be set appropriately to one or more.

In addition, while the present embodiments will be described by way of an example in which the one or more ejection holes 95 are provided in the upper dummy region alone, the present embodiments are not limited thereto. For example, the one or more ejection holes 95 may be provided in both of the product region and the dummy region. In such a case, the number of the one or more ejection holes 95 arranged in one stage may be changed. For example, the number of the one or more ejection holes 95 arranged in the dummy region may be set to be greater than the number of the one or more ejection holes 95 arranged in the product region (or the number of the one or more ejection holes 95 arranged in one stage in the dummy region may be set to three and the number of the one or more ejection holes 95 arranged in one stage in the product region may be set to one) such that the assist gas is ejected more into the dummy region than into the product region.

### Fifth Ejector

The nozzle 26 is provided with a plurality of ejection holes 96 facing the product region of the process chamber 11. The nozzle 26 is configured such that the second source gas is supplied to the product wafers and the dummy wafers through the ejection holes 96. In addition, the ejection holes 96 may be provided in both of the product region and the dummy region, or may be provided in the product region alone.

### Sixth Ejector

The nozzle 27 is provided with a plurality of ejection holes (not shown) facing the product region of the process chamber 11. The ejection holes of the nozzle 27 may be provided in both of the product region and the dummy region, or may be provided in the product region alone.

The nozzle 27 is configured such that the assist gas is supplied to the product wafers through the ejection holes of the nozzle 27. By using the nozzle 27, it is possible to adjust a uniformity on surfaces of the entire product wafers.

In addition, the assist gas is supplied through the nozzle 25 and the nozzle 27 when the first source gas is being supplied through the nozzles 22 and 23, when the second source gas is being supplied through the nozzle 24 and the nozzle 26, or when both the first source gas and the second source gas are being supplied.

In addition, according to the present embodiments, the nozzle 25 and the nozzle 27 are arranged such that the nozzle 22, the nozzle 23, the nozzle 24 and the nozzle 26 are interposed therebetween. Further, the assist gas is supplied through the nozzle 27 when the first source gas is being supplied through the nozzles 22 and 23. The first source gas serves as a source gas of a Group 14 element. As the source gas of the Group 14 element, for example, a gas containing an element such as carbon (C), silicon (Si), germanium (Ge), tin (Sn) and lead (Pb) may be used. In addition, according to the present embodiments, the first source gas may be a source gas containing an element other than the Group 14 element.

### Controller

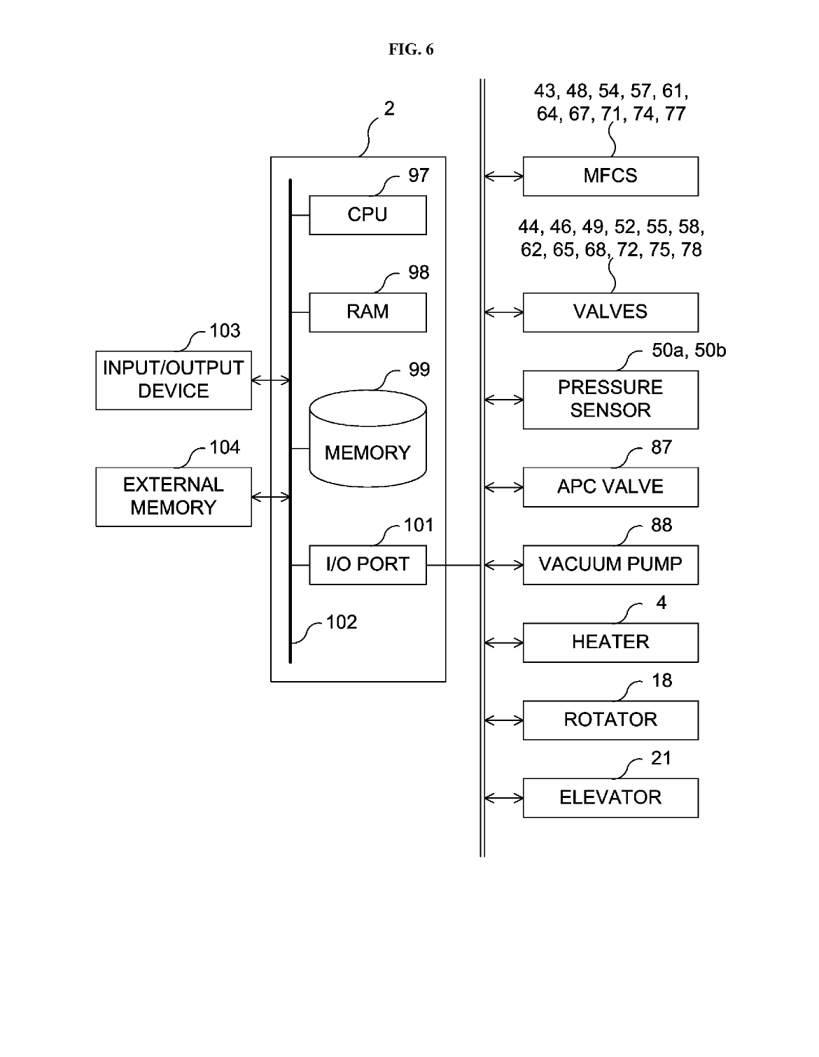

FIG. 6 is a block diagram schematically illustrating the substrate processing apparatus 1, and the controller (which is a control structure) 2 of the substrate processing apparatus 1 may be embodied by a computer. The computer includes a CPU (Central Processing Unit) 97, a RAM (Random Access Memory) 98, a memory 99 and an I/O port (input/output port) 101.

The RAM 98, the memory 99 and the I/O port 101 are configured to exchange data with the CPU 97 through an internal bus 102. For example, an input/output device 103 configured by a component such as a touch panel may be connected to the controller 2.

For example, the memory 99 is configured by a component such as a flash memory and a hard disk drive (HDD). For example, a control program configured to control operations of the substrate processing apparatus 1 or a process recipe containing information on procedures and conditions of a substrate processing described later may be readably stored in the memory 99.

The process recipe is obtained by combining steps (procedures) of the substrate processing described later such that the controller 2 can execute the steps by using the substrate processing apparatus 1 to acquire a predetermined result, and functions as a program. Hereinafter, the process recipe and the control program may be collectively or individually referred to as a “program”.

Thus, in the present specification, the term “program” may refer to the process recipe alone, may refer to the control program alone, or may refer to both of the process recipe and the control program. The RAM 98 functions as a memory area (work area) where a program or data read by the CPU 97 is temporarily stored.

The I/O port 101 is connected to components mentioned above such as the MFCs 43, 48, 54, 57, 61, 64, 67, 71, 74 and 77, the valves 44, 46, 49, 52, 55, 58, 62, 65, 68, 72, 75 and 78, the pressure sensors 50a and 50b, the APC valve 87, the vacuum pump 88, the heater 4, the temperature sensor, the rotator 18 and the elevator 21.

The CPU 97 is configured to read and execute the control program stored in the memory 99, and to read the process recipe stored in the memory 99 in accordance with an instruction such as an operation command inputted via the input/output device 103.

For example, in accordance with contents of the process recipe read from the memory 99, the CPU 97 is configured to be capable of controlling various operations such as flow rate adjusting operations for various gases by the MFCs 43, 48, 54, 57, 61, 64, 67, 71, 74 and 77, opening and closing operations of the valves 44, 46, 49, 52, 55, 58, 62, 65, 68, 72, 75 and 78 and an opening and closing operation of the APC valve 87. In addition, the CPU 97 is configured to be capable of controlling various operations such as a pressure adjusting operation by the APC valve 87 based on the pressure sensors 50a and 50b, a start and stop of the vacuum pump 88 and a temperature adjusting operation by the heater 4 based on the temperature sensor. In addition, the CPU 97 is configured to be capable of controlling various operations such as an operation of adjusting a rotation and a rotation speed of the boat 12 by the rotator 18 and an elevating and lowering operation of the boat 12 by the elevator 21.

For example, the controller 2 is not limited to a dedicated computer, and may be embodied by a general-purpose computer. For example, the controller 2 according to the present embodiments may be embodied by preparing an external memory 104 storing the program and by installing the program onto the general-purpose computer using the external memory 104. For example, the external memory 104 may include a magnetic disk such as a hard disk, an optical disk such as a CD, a magneto-optical disk such as an MO and a semiconductor memory such as a USB memory. In addition, the controller 2 is not limited to being provided in the substrate processing apparatus 1, but may be configured as a server capable of controlling a plurality of substrate processing apparatuses.

### Substrate Processing Method

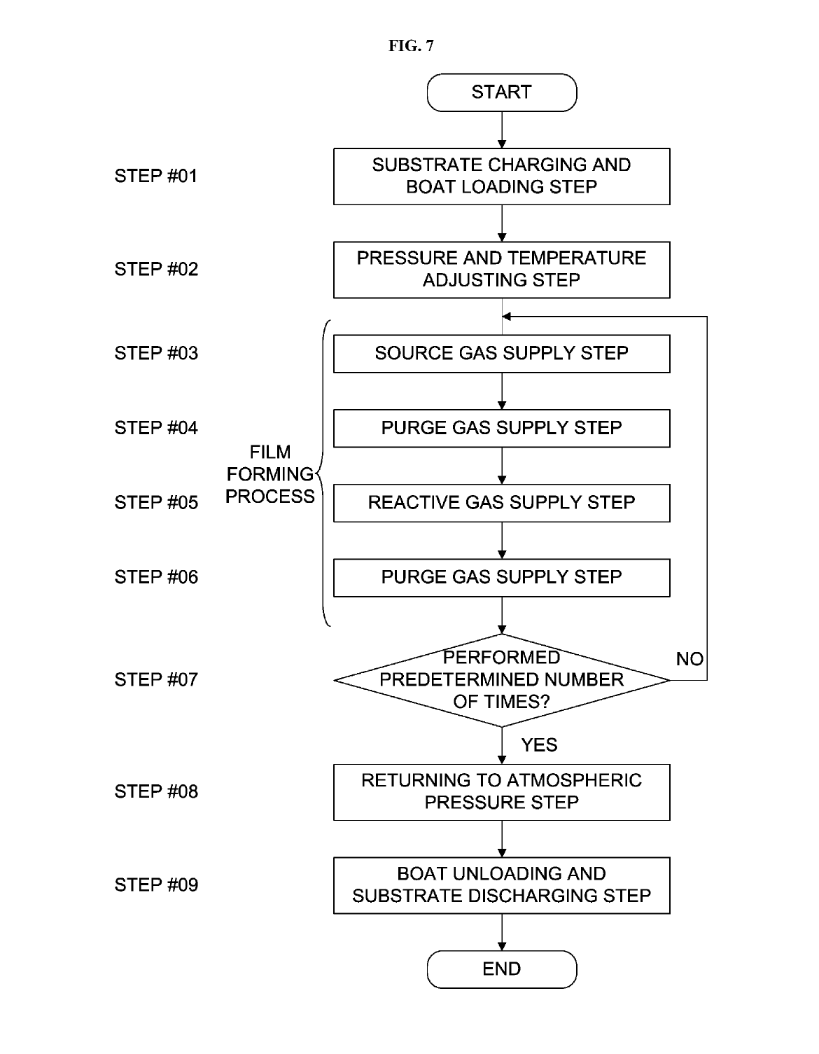

Subsequently, an example of the substrate processing will be described with reference to FIG. 7. Hereinafter, as an example of a manufacturing process of a semiconductor device, a cycle process of performing a film processing by alternately supplying a source (source material) serving as the first source gas and a reactant (reactive gas) serving as the second source gas to the process chamber 11 will be described. According to the present embodiments, an example of forming a silicon nitride film (Si₃N₄ film, hereinafter also referred to as a “SiN film”) on the substrate will be described. The SiN film is formed by using a silicon source gas serving as an example of the source and a nitrogen-containing gas serving as the reactant.

In the film forming process according to the present embodiments, the SiN film is formed on the wafer 9 by performing a cycle a predetermined number of times (once or more times). For example, the cycle includes: a step of supplying the source gas (first source gas) to the wafer 9 in the inner tube 6 (film forming step #1: STEP #03 in FIG. 7); a step of purging the source gas remaining in the inner tube 6 from the inner tube 6 (film forming step #2: STEP #04 in FIG. 7); a step of supplying the nitrogen-containing gas serving as the reactive gas (second source gas) to the wafer 9 in the inner tube 6 (film forming step #3: STEP #05 in FIG. 7); and a step of purging the nitrogen-containing gas remaining in the inner tube 6 from the inner tube 6 (film forming step #4: STEP #06 in FIG. 7 ). The steps in the cycle are performed non-simultaneously.

First, in STEP #01 in FIG. 7, the wafers 9 are loaded into the boat 12. By transferring (loading) the boat 12 into the inner tube 6, the wafers 9 in the boat 12 are accommodated in the cylinder of the inner tube 6. Subsequently, in STEP #02 in FIG. 7, after the boat 12 is loaded into the inner tube 6, a pressure (inner pressure) and a temperature (inner temperature) of the inner tube 6 are adjusted. Subsequently, the four steps of the film forming step (that is, the film forming step #1 to the film forming step #4) are performed sequentially. Hereinafter, each of the four steps of the film forming step is described in detail.

### Film Forming Step #1

In the film forming step #1 (that is, in STEP #03 in FIG. 7), for example, a flash supply of the first source gas is performed in a manner mentioned above. For example, with the valve 44 open and the valve 46 closed, the first source gas supplied from the source gas supply source 42 by the MFC 43 is supplied to the tank 45. Similarly, with the valve 49 open and the valve 52 closed, the first source gas supplied from the source gas supply source 47 by the MFC 48 is supplied to the tank 51. In the present step, an accumulation time and a flow rate of the first source gas supplied to each of the tanks 45 and 51 are set such that an amount of the first source gas supplied to each of the tanks 45 and 51 is equal to or greater than a minimum amount at which the flash supply can be performed with respect to the tanks 45 and 51, and such that the same amount of the first source gas can be accumulated in the tanks 45 and 51.

When a predetermined amount of the first source gas is accumulated in each of the tank 45 and the tank 51, the valve 44 is closed and the valve 46 is opened to release the first source gas from the tank 45. Thereby, the flash supply of the first source gas to the nozzle 22 is performed. Simultaneously, the valve 49 is closed and the valve 52 is opened to release the first source gas from the tank 51. Thereby, the flash supply of the first source gas to the nozzle 23 is performed. In other words, the nozzles 22 and 23 are configured to eject the same gas at substantially the same flow rate at the same time (that is, simultaneously). Therefore, it is possible to supply a large amount of the first source gas into the process chamber 11 without increasing a pressure (inner pressure) of the nozzle 22 and a pressure (inner pressure) of the nozzle 23. In addition, during the flash supply of the first source gas, the vacuum pump 88 is controlled to maintain a pressure of an atmosphere (inner atmosphere) of the main exhaust slit 82 or the exhaust space S at a predetermined pressure or less. In addition, a pressure (inner pressure) of the main exhaust slit 82 is maintained within a range from 1 Pa to 3,000 Pa, and preferably maintained at 300 Pa or less. When the inner pressure of the main exhaust slit 82 is 300 Pa or less, it is possible to set an average flow velocity of the first source gas to be 10 m/s or more.

When the first source gas is supplied, the first source gas is simultaneously ejected toward the wafer 9 through the nozzles 22 and 23 via the ejection holes 92 and the ejection holes 93, respectively. The first source gas is ejected along the five main stream lines such that the first source gas is diffused radially at flow velocities with peaks in at least five different directions, and the source gas ejected as described above is exhausted to an outside (outer portion) of the cylinder through the main exhaust slit 82 and the two subsidiary exhaust slits 83a and 83b. In such a state, the average flow velocity of the first source gas supplied in the flash flow manner through the nozzles 22 and 23 is set to a predetermined flow velocity on a predetermined plane parallel to the wafer 9 within the process vessel. For example, the average flow velocity of the first source gas is set appropriately to a value from 1 m/s to 200 m/s, and preferably, 10 m/s or higher. With the flow velocity of 10 m/s or higher, it is possible to diffuse the first source gas over the entirety of the wafer 9 while maintaining the low degree of decomposition of the first source gas.

In addition, the flow rate (substantially the same flow rate) of the first source gas supplied through the nozzles 22 and 23 can such as not to cause an unsteady backflow passing through the imaginary plane β directly facing the ejection holes 92 and the ejection holes 93 on the central axis of the wafer 9, over the wafer 9 excluding an area in the vicinity of the inner wall of inner tube 6, in a direction approaching the ejection holes 92 and the ejection holes 93. Thereby, it is possible to suppress an occurrence of a steady backflow during the flash supply. In addition, in the film forming step #1, the inert gas from the inert gas supply sources 66 and 69 may be used as the carrier gas.

For example, as the first source gas supplied through the gas supply pipe 31 and the gas supply pipe 32, the silicon source gas mentioned above may be used. For example, as the first source gas, a gas containing silicon and halogen may be used. For example, as the gas containing silicon and halogen, an inorganic chlorosilane-based gas such as tetrachlorosilane (SiCl₄, abbreviated as STC) gas, hexachlorodisilane (Si₂Cl₆, abbreviated as HCDS) gas and octachlorotrisilane (Si₃Cl₈, abbreviated as OCTS) gas may be used. For example, as the gas containing silicon and halogen, one or more of the gases mentioned above may be used. The first source gas corresponds to a first source material according to the present embodiments. In addition, according to the present embodiments, the first source material is not limited to a gaseous substance. For example, the first source material may be a liquid substance such as a mist substance.

In addition, the assist gas such as N₂ is ejected toward the wafer 9 using the nozzle 25 and the nozzle 27. That is, according to the present embodiments, the assist gas is supplied through the nozzle 25 and the nozzle 27 when the first source gas is supplied through the nozzles 22 and 23.

### Film Forming Step #2

In the film forming step #2, the valves 46 and 52 are closed to stop a supply of the first source gas, and the valves 68 and 72 are opened to supply the inert gas (purge gas) from the inert gas supply sources 66 and 69 to the nozzles 22 and 23. In addition, for example, by controlling an exhaust pump such as the vacuum pump 88 and the APC valve 87, the reaction tube 5 is exhausted such that a pressure (inner pressure) of the reaction tube 5 can be adjusted (or set) to a predetermined pressure (that is, a vacuum degree), for example, 20 Pa or less, and such that the first source gas remaining in the inner tube 6 can be removed from the inner tube 6. In the present step, the assist gas is continuously supplied through the nozzle 25 and the nozzle 27. Thereby, it is possible to further improve an effect of purging the first source gas remaining in the inner tube 6.

### Film Forming Step #3

In the film forming step #3, the nitrogen-containing gas serving as the second source gas is supplied. With the valve 55 open, the second source gas supplied from the source gas supply source 53 and whose flow rate is adjusted by the MFC 54 is supplied into the inner tube 6 (that is, the cylinder) through the nozzle 24. Similarly, with the valve 62 open, the second source gas from the source gas supply source 59 and whose flow rate is adjusted by the MFC 61 is supplied into the inner tube 6 through the nozzle 26. The second source gas supplied through the nozzle 24 and the nozzle 26 is exhausted to an outside (outer portion) of the inner tube 6 through the main exhaust slit 82 and the subsidiary exhaust slits 83a and 83b. By supplying the second source gas, a silicon-containing film on a base film (underlying film) of the wafer 9 reacts with the second source gas. Thereby, it is possible to form the SiN film on the wafer 9.

According to the present embodiments, for example, as the second source gas, a gas such as ammonia (NH₃) gas may be used. That is, the NH₃ gas is supplied into the inner tube 6 while being exhausted through the plurality of exhaust slits. By supplying the NH₃ gas, the silicon-containing film on the base film (underlying film) of the wafer 9 reacts with the NH₃ gas. Thereby, it is possible to form the SiN film on the wafer 9. The second source gas corresponds to a second source material according to the present embodiments. In addition, according to the present embodiments, the second source material is not limited to a gaseous substance. For example, the second source material may be a liquid substance such as a mist substance.

Additionally, in the film forming step #3, the assist gas is continuously supplied through the nozzle 25 and the nozzle 27. That is, according to the present embodiments, the assist gas is supplied through the nozzle 25 and the nozzle 27 when the second source gas is supplied through the nozzle 24 and the nozzle 26.

### Film Forming Step #4

In the film forming step #4, the valves 55 and 62 are closed to stop a supply of the second source gas, and the valves 75 and 78 are opened to supply the inert gas (purge gas) from the inert gas supply sources 73 and 76 to the nozzle 24 and the nozzle 26. In addition, for example, by controlling the exhaust pump such as the vacuum pump 88 and the APC valve 87, the reaction tube 5 is exhausted such that the pressure (inner pressure) of the reaction tube 5 can be adjusted (or set) to the predetermined pressure (that is, the vacuum degree), for example, 20 Pa or less, and such that the second source gas remaining in the inner tube 6 can be removed from the inner tube 6. In the present step, the assist gas is continuously supplied through the nozzle 25 and the nozzle 27. Thereby, it is possible to further improve an effect of purging the second source gas remaining in the inner tube 6.

According to the present embodiments, the cycle includes the film forming steps #1 to #4 mentioned above. In STEP #07 in FIG. 7, by determining whether the cycle including the film forming steps #1 to #4 is performed the predetermined number of times, it is possible to form the SiN film of a predetermined thickness on the wafer 9. According to the present embodiments, the cycle including the film forming steps #1 to #4 is repeatedly performed a plurality number of times. However, according to the present embodiments, the cycle including the film forming steps #1 to #4 may be performed once without being repeatedly performed.

After the film forming process mentioned above is completed (that is, the cycle including the film forming steps #1 to #4 is performed the predetermined number of times), in STEP #08 in FIG. 7, the inner pressure of the inner tube 6 is returned to a normal pressure (that is, the atmospheric pressure). For example, the inert gas such as the N₂ gas is supplied into the inner tube 6 and then exhausted. Thereby, an inside (inner portion) of the inner tube 6 is purged with the inert gas, and a substance such as the gas remaining in the inner tube 6 is removed from the inner tube 6 (purge by the inert gas). Thereafter, an atmosphere (inner atmosphere) of the inner tube 6 is replaced with the inert gas (substitution by the inert gas), and the inner pressure of the inner tube 6 is returned to the normal pressure.

Then, in STEP #09 in FIG. 7, the wafer 9 is unloaded (or removed) from the inner tube 6. Thereby, the substrate processing according to the present embodiments is completed. A method of manufacturing a semiconductor device according to the present embodiments may be constituted by the steps mentioned above.

Hereinafter, a flow of the first source gas within the nozzles 22 and 23 will be described. Since shapes of the nozzles 22 and 23 are the same (or substantially the same), the flow of the first source gas within the nozzle 22 will be mainly described.

When the first source gas is supplied through the end structure 22c, the first source gas flows from the lower end toward the upper end of the transition structure 22a. Since the cross-sectional area of the transition structure 22a gradually increases toward the upper end of the transition structure 22a, a pressure of the first source gas decreases as the first source gas flows upward in the transition structure 22a. In addition, the first source gas flowing into the cylinder 22b flows upward within the cylinder 22b while being ejected into the inner tube 6 through the ejection holes 92 at each stage.

In addition, when the flow rate of the first source gas is increased without changing the cross-sectional area of the cylinder 22b, excess fluid energy (that is, kinetic energy, potential energy, pressure energy and, internal energy) may remain, and the pressure will increase quadratically toward an upper end (tip) of the cylinder 22b. In such a case, the flow rate of the first source gas ejected through an upper stage ejection hole among the ejection holes 92 is greater than the flow rate of the first source gas ejected through a lower stage ejection hole among the ejection holes 92. As a result, a difference in the flow rate of the first source gas between an upper portion (tip) and a lower portion (base) of the cylinder 22b. In other words, the flow rate that can be supplied uniformly depends on the cross-sectional area. In addition, when the flow rate of the first source gas is increased, an oscillatory flow may also occur in the lower portion of the cylinder 22b.

On the other hand, when the flow rate of the first source gas is set to an appropriate flow rate for the nozzle 22, it is possible to reduce a difference in an internal pressure (inner pressure) between the upper and lower ends of the cylinder 22b. In other words, by adjusting the flow rate of the first source gas and the cross-sectional area of the cylinder 22b of the nozzle 22, it is possible to suppress an increase in the internal pressure at the tip (front end) of the cylinder 22b, and it is also possible to prevent an asymmetric flow of the first source gas.

According to the present embodiments, the cross-sectional area of the cylinder 22b of the nozzle 22 and the cross-sectional area of the cylinder 23b of the nozzle 23 are set such that the flow rate is equal to or less than a predetermined level capable of preventing the internal pressure from increasing quadratically from the lower stage ejection hole to the upper stage ejection hole among the ejection holes 92.

### Functions and Effects

According to the present embodiments, it is possible to obtain one or more of the effects described below.

According to the present embodiments, the nozzles 22 and 23 are provided with the cylinders 22b and 23b extending upward from the upper ends of the transition structures 22a and 23a, respectively. That is, the cross-sectional area (flow path area) of each of the cylinders 22b and 23b is set to be greater than that of each of the end structures 22c and 23c. Therefore, since the flow path area of each of the nozzles 22 and 23 can be expanded, even when supplying the gas in the flash flow manner at a high flow rate, it is possible to suppress the backflow by uniformly ejecting the gas onto the surface of the wafer 9. It is also possible to improve a film forming performance on the surface of the wafer 9.

According to the present embodiments, the nozzles 22 and 23 are provided with the plurality of ejection holes arranged in a direction substantially parallel to the surface of the wafer 9, that is, the ejection holes 92 and the ejection holes 93, respectively. In addition, the nozzles 22 and 23 are configured such that the gas is supplied radially through the ejection holes 92 and the ejection holes 93 into the inner tube 6 (that is, the process chamber 11) along the five main stream lines. Therefore, it is possible to widen a gas flow within the inner tube 6, and it is also possible to suppress the backflow. In addition, since the gas stagnation within the inner tube 6 is suppressed, it is possible to improve a supply efficiency of the source gas, to improve a gas replacement, and to improve the partial pressure of the gas within the inner tube 6. In addition, it is possible to improve a uniformity of the wafer 9 on the surface thereof during the film forming process, and it is also possible to form the film on a side surface of the fine structure such as a fine hole and a groove.

In addition, the farther away each of the nozzles 22 and 23 is from each opposing nozzle, the greater a distance from the wafer 9 becomes. That is, a distance between the wafer 9 and the front surface of each of the nozzles 22 and 23 increases as the nozzles 22 and 23 are spaced farther apart from the other one of the nozzles 22 and 23. The normals to the nozzles 22 and 23 at the positions (where the ejection holes 92 and the ejection holes 93 are located) are configured such that the angles with respect to the reference direction monotonically increase in the arrangement order of the ejection holes. As a result, except for the ejection hole closest to the opposing nozzle, the gases ejected through the ejection holes 92 and the ejection holes 93 can be prevented from joining together and strengthening each other. Thereby, it is possible to uniformize the flow rate of the gas within the inner tube 6.

In addition, the ejection holes 92 and the ejection holes 93 are formed along a direction perpendicular to the thickness directions of the nozzles 22 and 23. As a result, the gas ejected through each of the ejection holes 92 and the ejection holes 93 is strongly directed in the direction perpendicular to the thickness directions of the nozzles 22 and 23. Thereby, it is possible to prevent the gases ejected through the ejection holes 92 and the ejection holes 93 from joining together, and it is also possible to uniformize the flow rate of the gas within the inner tube 6.

In addition, the nozzles 22 and 23 are provided with the transition structures 22a and 23a and the cylinders 22b and 23b, respectively, and the transition structures 22a and 23a are configured such that their cross-sectional areas gradually increase upward. In other words, a flow path area at each of upper ends (tips) of the nozzles 22 and 23 is set to be greater than a flow path area at each of lower ends (bases) of the nozzles 22 and 23. Thereby, it is possible to suppress an increase in a pressure (internal pressure) at each of the tips (front ends) of the nozzles 22 and 23.

In addition, the ejection holes 92 and the ejection holes 93 are arranged on the same plane, and heights of the ejection holes 92 and heights of the ejection holes 93 correspond to heights of the wafers 9 arranged in a multistage manner. As a result, it is possible to widen and uniformize the flow of the gas supplied to each of the wafers 9, and it is also possible to improve the uniformity of the wafer 9 on the surface thereof, and to improve a uniformity between the wafers 9. In addition, since at least one of the ejection holes 92 and at least one of the ejection holes 93 directly face the main exhaust slit 82, it is possible to suppress the gas stagnation.

In addition, according to the present embodiments, the nozzles 25 and 27 through which the assist gas is supplied are arranged with the nozzles 22, 23, 24 and 26 interposed therebetween. As a result, since the first source gas and the second source gas can be diluted by the assist gas supplied through the nozzles 25 and 27, it is possible to improve the supply efficiency of each source gas. Further, by using the nozzles 25 and 27, it is possible to improve the gas replacement during the film forming process, and it is also possible to suppress a return flow of the gas (which is supplied through the supply buffer 8) to the supply buffer 8 caused by phenomena such as the vortex and a turbulence in the process chamber 11, that is, the backflow.

In addition, according to the present embodiments, when the first source gas is supplied through the nozzles 22 and 23 or when the second source gas is supplied through the nozzles 24 and 26, the assist gas is supplied through the nozzles 25 and 27. Therefore, it is possible to improve the supply efficiency of the source gas, and to improve the gas replacement. It is also possible to suppress the backflow.

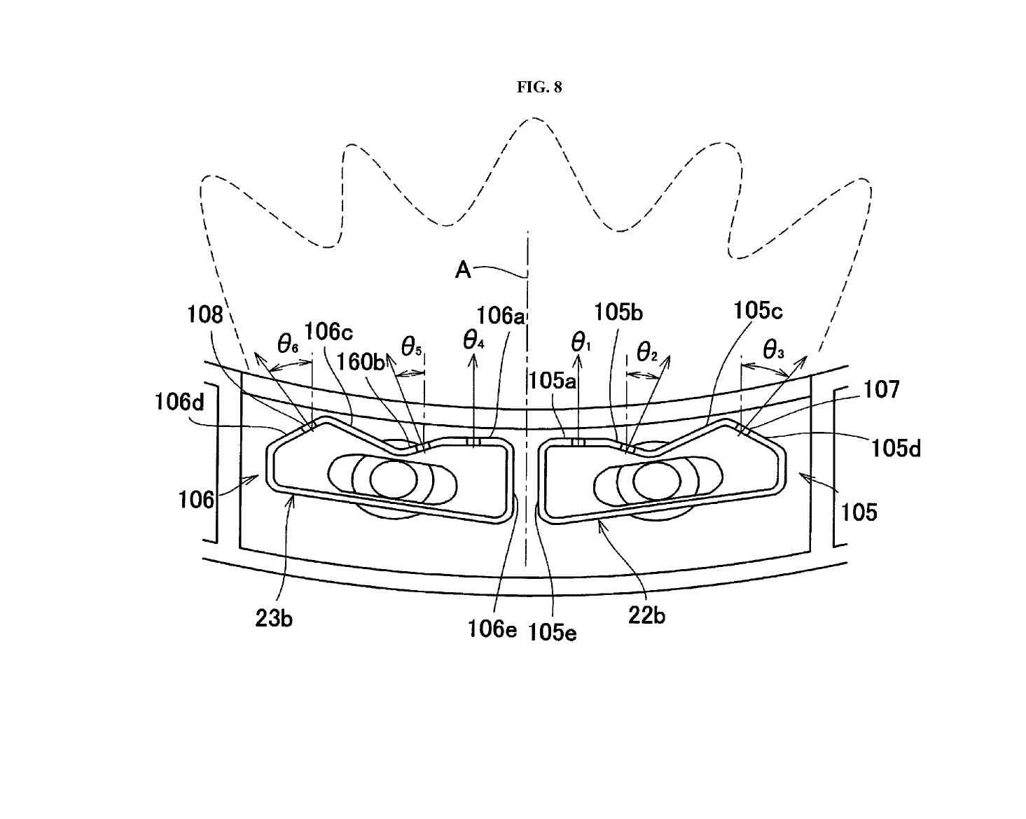

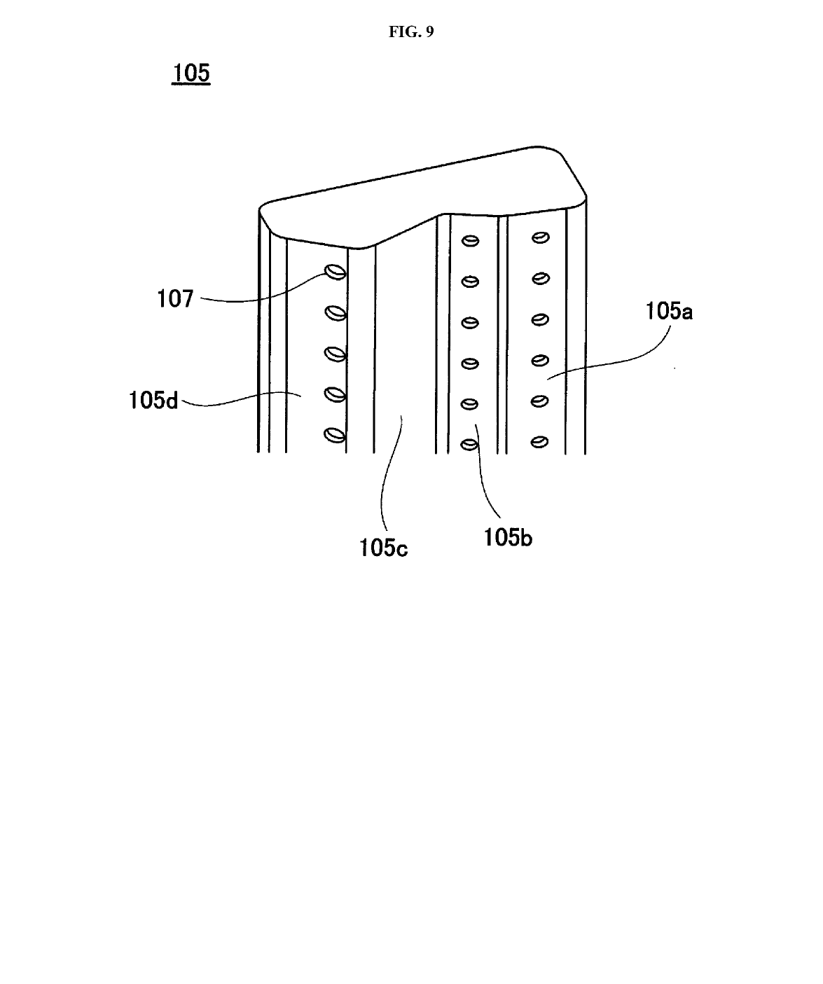

In addition, according to the present embodiments, the first source gas supplied to the nozzles 22 and 23 is ejected in the five directions along the five main stream lines. However, the shape of the nozzle is not limited to that of each of the nozzles 22 and 23 shown in FIG. 4. For example, in FIGS. 8 and 9, nozzles 105 and 106 (which are modified from the nozzles 22 and 23) according to a modified example are shown.

When a plane passing through the reference direction A and perpendicular to the surface of wafer 9 is set as a reference plane, a front surface of the nozzle 105 is provided with: a first flat structure (first flat portion) 105a extending in a direction away from the reference plane; a second flat structure (second flat portion) 105b continuing from the first flat structure 105a and extending in the direction away from the reference plane and in a direction away from the wafer 9; a third flat structure (third flat portion) 105c continuing from the second flat structure 105b and extending in the direction away from the reference plane and in a direction toward the wafer 9; and a fourth flat structure (fourth flat portion) 105d continuing from the third flat structure 105c and extending in the direction away from the reference plane and in the direction away from the wafer 9. In other words, the front surface of the nozzle 105 is provided with a concave portion (a concave structure or a recess) recessed in the direction away from the wafer 9.

In addition, ejection holes 107 are perforated (provided) at the first flat structure 105a, the second flat structure 105b and the fourth flat structure 105d. Each of the ejection holes 107 is substantially perpendicular to a thickness direction of the nozzle 105. When a direction away from the reference plane and away from the wafer 9 is defined as a “first direction” and a direction away from the reference plane and farther away from the wafer 9 than the first direction is defined as a “second direction”, then the second flat structure 105b may also be referred to as a “first flat structure facing toward the first direction”, the fourth flat structure 105d may also be referred to as a “second flat structure facing toward the second direction”, and the third flat structure 105c may also be referred to as a “connecting surface connecting the first and second flat structures and facing toward a direction approaching the reference plane”.

When an inclination angle of a main stream line (normal) relative to the reference direction A at a location (position) where the ejection hole 107 of the first flat structure 105a is located is defined as θ₁, an inclination angle of a main stream line (normal) relative to the reference direction A at a location (position) where the ejection hole 107 of the second flat structure 105b is located is defined as θ₂, and an inclination angle of a main stream line (normal) relative to the reference direction A at a location (position) where the ejection hole 107 of the fourth flat structure 105d is located is defined as θ₃, a relationship between the inclination angles is “θ₁ < θ₂ < θ₃”, that is, θ₁ is less than θ₂, and θ₂ is less than θ₃. In addition, the main stream line (normal) of the ejection hole 107 of the first flat structure 105a is substantially parallel to the reference direction A, and θ₁ is ± 5°. In addition, an angle between the main stream line (normal) of the ejection hole 107 of the first flat structure 105a and the main stream line (normal) of the ejection hole 107 of the fourth flat structure 105d is 90° or less.

The nozzle 106 is provided as a mirror image of the nozzle 105, and is arranged such that a flat surface 106e is adjacent to a flat surface 105e and is parallel or substantially parallel to the flat surface 105e. Similar to the nozzle 105, a front surface of the nozzle 106 is provided with: a first flat structure (first flat portion) 106a extending in the direction away from the reference plane; a second flat structure (second flat portion) 106b continuing from the first flat structure 106a and extending in the direction away from the reference plane and in the direction away from the wafer 9; a third flat structure (third flat portion) 106c continuing from the second flat structure 106b and extending in the direction away from the reference plane and in the direction toward the wafer 9; and a fourth flat structure (fourth flat portion) 106d continuing from the third flat structure 106c and extending in the direction away from the reference plane and in the direction away from the wafer 9. In other words, the front surface of the nozzle 106 is provided with a concave portion (a concave structure or a recess) recessed in the direction away from the wafer 9.

In addition, ejection holes 108 are perforated (provided) at the first flat structure 106a, the second flat structure 106b and the fourth flat structure 106d. Each of the ejection holes 108 is substantially perpendicular to a thickness direction of the nozzle 106.

When an inclination angle of a main stream line (normal) relative to the reference direction A at a location (position) where the ejection hole 108 of the first flat structure 106a is located is defined as θ₄, an inclination angle of a main stream line (normal) relative to the reference direction A at a location (position) where the ejection hole 108 of the second flat structure 106b is located is defined as θ₅, and an inclination angle of a main stream line (normal) relative to the reference direction A at a location (position) where the ejection hole 108 of the fourth flat structure 106d is located is defined as θ₆, a relationship between the inclination angles is “θ₄ < θ₅ < θ₆”, that is, θ₄ is less than θ₅, and θ₅ is less than θ₆. In addition, the main stream line (normal) of the ejection hole 108 of the first flat structure 106a is substantially parallel to the reference direction A, and θ₄ is ± 5°. In addition, an angle between the main stream line (normal) of the ejection hole 108 of the first flat structure 106a and the main stream line (normal) of the ejection hole 108 of the fourth flat structure 106d is 90° or less.

By arranging the nozzles 105 and 106 as described above, θ₁ = θ₄ or θ₁ ≈ θ₄, θ₂ = θ₅ or θ₂ ≈ θ₅, and θ₃ = θ₆ or θ₃ ≈ θ₆, that is, θ₁ is equal to or substantially equal to θ₄, θ₂ is equal to or substantially equal to θ₅, and θ₃ is equal to or substantially equal to θ₆. In such a state, the main stream lines of centermost ejection holes (that is, the ejection hole (among the ejection holes 107) of the nozzle 105 and the ejection hole (among the ejection holes 108) of the nozzle 106 closest to each opposing nozzle related thereto) are substantially parallel to the reference direction A, and the ejection hole of the nozzle 105 and the ejection hole of the nozzle 106 closest to each opposing nozzle related thereto are formed on substantially the same tangent plane such that the first source gas from the nozzle 105 and the first source gas from the nozzle 106 can be ejected substantially parallel to each other. Therefore, the main stream lines of the ejection hole of the nozzle 105 and the ejection hole of the nozzle 106 closest to each opposing nozzle related thereto can be considered to be the same main stream line.

According to the present modified example of the present disclosure, the first source gas supplied to the nozzles 105 and 106 is ejected in the five directions along the five main stream lines. Therefore, according to the present modified example, it is possible to obtain substantially the same effects as in the embodiments mentioned above. According to the present modified example, since greater flexibility in an ejection direction and spacing of the ejection holes can be provided, it is possible to more efficiently use the space of the nozzle chamber to supply the gas at a high flow rate.

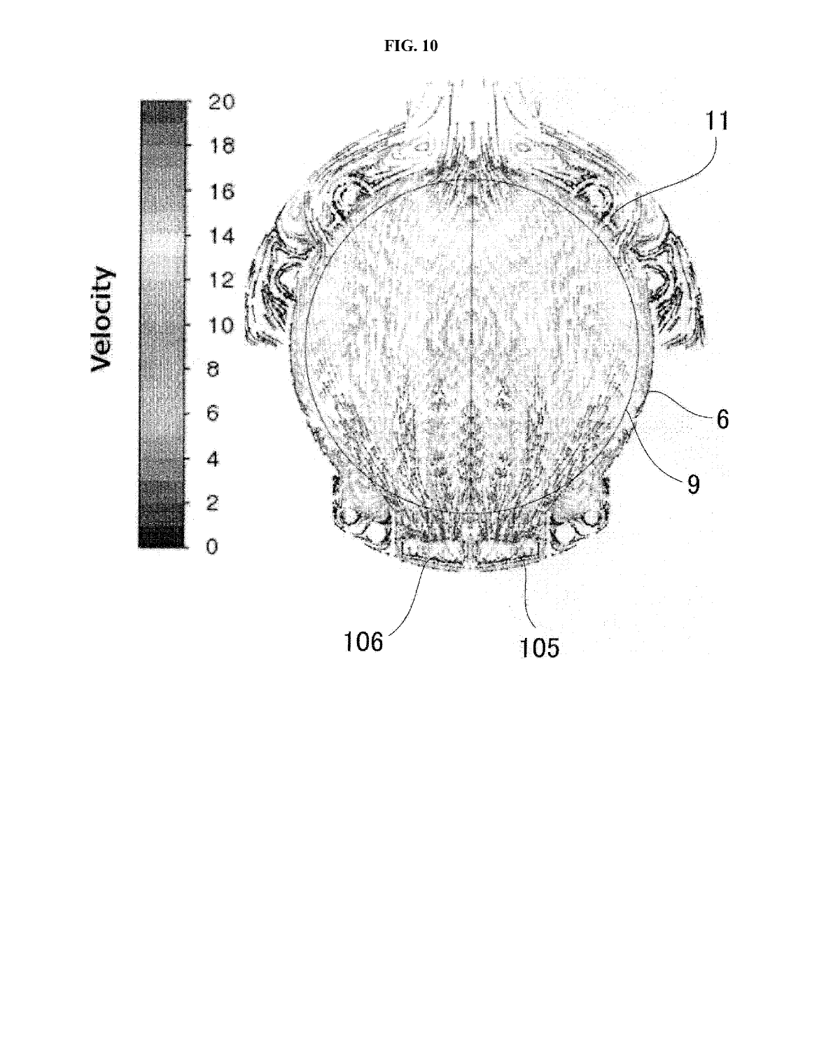

FIG. 10 is a diagram schematically illustrating results of a simulation of a flow velocity distribution on the surface of the wafer 9 at a predetermined height when the first source gas is supplied through the nozzles 105 and 106. According to the present modified example, widths and normal directions of the first flat structures 105a and 106a, the second flat structures 105b and 106b, and the fourth flat structures 105d and 106d, as well as a diameter of each of the ejection holes 107, are optimized through such a simulation. Therefore, as shown in FIG. 10, the first source gas ejected through each of the ejection holes 107 and each of the ejection holes 108 can be diffused along the five main stream lines without meandering up to the imaginary plane β, that is, a position where a horizontal width inside the inner tube 6 (that is, the process chamber 11) is greatest. The flow passing through the imaginary plane β in a reverse direction is suppressed small enough to be substantially negligible. As a result, it is possible to prevent (or suppress) the backflow and the turbulence from occurring within the inner tube 6.

In addition, the front surface of each of the nozzles 105 and 106 is provided with the concave portion (the concave structure or the recess) recessed in the direction away from the wafer 9, and the cross-sectional area of the cylinder of each of the nozzles 105 and 106 can be further increased. As a result, even when the flow rate of the first source gas is increased, it is possible to uniformly eject the source gas onto the surface of the wafer 9.

In addition, the embodiments and the modified examples mentioned above may be appropriately combined. Process procedures and process conditions of each combination thereof may be substantially the same as those of the embodiments mentioned above or the modified examples mentioned above. Further, the technique of the present disclosure is described in detail by way of the embodiments and the modified examples mentioned above. However, the descriptions and the drawings constituting part of the present disclosure should not be understood as limiting the technique of the present disclosure. That is, the technique of the present disclosure is not limited to the embodiments and the modified examples mentioned above, and may be modified in various ways without departing from the scope thereof. For example, the technique of the present disclosure may be applied to other processes such as an oxidation process.

For example, the embodiments and the modified examples mentioned above are described by way of an example in which a batch type substrate processing apparatus capable of simultaneously processing a plurality of substrates is used to form a film. However, the technique of the present disclosure is not limited thereto. For example, the technique of the present disclosure may be preferably applied when a single wafer type substrate processing apparatus capable of simultaneously processing one or several substrates is used to form the film. For example, the embodiments and the modified examples mentioned above are described by way of an example in which a substrate processing apparatus including a hot wall type process furnace is used to form the film. However, the technique of the present disclosure is not limited thereto. For example, the technique of the present disclosure may be preferably applied when a substrate processing apparatus including a cold wall type process furnace is used to form the film.

Process procedures and process conditions of each process using the substrate processing apparatuses exemplified above may be substantially the same as those of the embodiments or the modified examples mentioned above. Even in such a case, it is possible to obtain substantially the same effects as in the embodiments or the modified examples mentioned above.

In addition, for example, the processing executed by the CPU 97 by reading the program (software) in the embodiments mentioned above may be executed by various processors other than the CPU 97. In such a case, for example, a PLD (Programmable Logic Device) such as an FPGA (Field Programmable Gate Array) whose circuit configuration can be changed after manufactured and a dedicated electrical circuit including a circuit configuration designed exclusively for executing a specific process such as an ASIC (Application Specific Integrated Circuit) may be used as such a processor.

For example, the processing may be executed by one of the various processors, or may be executed by a combination of two or more processors of the same or different types (for example, a plurality of FPGAs or a combination of the CPU 97 and the FPGA). More specifically, a hardware structure of each of the various processors is an electric circuit that combines circuit elements such as semiconductor devices.

For example, the embodiments and the modified examples mentioned above are described by way of an example in which the program for processing the substrate is stored (installed) in the memory 99 such as a ROM and a storage in advance. However, the technique of the present disclosure is not limited thereto. For example, the program may be provided in a form stored in a non-transitory storage medium (recording medium) such as a CD-ROM (Compact Disk Read Only Memory) and a DVD-ROM (Digital Versatile Disk Read Only Memory). The program may be downloaded from an external apparatus via a network.

In addition, the technique of the present disclosure may be configured by partially combining configurations included in the embodiments and the modified examples mentioned above. In the technique of the present disclosure configured by such a combination, the process procedures and the process conditions of each process may be substantially the same as those of the embodiments and the modified examples mentioned above. Even in such a case, it is possible to obtain substantially the same effects as in the embodiments or the modified examples mentioned above. The technique of the present disclosure includes various embodiments which are not described above, and the scope of the technique of the present disclosure is defined only by specific features in the claims that are appropriate from the above descriptions.

As described above, according to some embodiments of the present disclosure, it is possible to suppress the backflow by increasing the flow path area of the nozzle.

What is claimed is:

1. An ejection apparatus comprising
a first nozzle and a second nozzle facing a peripheral edge of a substrate and extending in a direction perpendicular to a main surface of the substrate,
wherein each of the first and second nozzles is provided with:
a front surface continuously formed on a side thereof facing the substrate; and
a plurality of ejection holes arranged on the front surface in a direction parallel to the main surface of the substrate, wherein a gas is ejected through the plurality of ejection holes toward the substrate, and
wherein, when a direction from a center of an arrangement of the first and second nozzles toward a center of the substrate is defined as a reference direction, the front surface of each of the first nozzle and the second nozzle is formed such that an angle of a normal to the front surface relative to the reference direction at positions where the plurality of ejection holes are located increases in an arrangement order of the plurality of ejection holes, and
wherein, among the plurality of ejection holes of each of the first nozzle and the second nozzle, an ejection hole of the first nozzle closest to the second nozzle and an ejection hole of the second nozzle closest to the first nozzle are located on a substantially same tangent plane such that the gas is ejected from the first nozzle in a direction substantially parallel to the gas ejected from the second nozzle.

2. The ejection apparatus of claim 1, wherein the first nozzle is provided with a side surface facing the second nozzle and the second nozzle is provided with a side surface facing the first nozzle, and
wherein each of the side surfaces is formed substantially parallel to a radial direction from a center of the substrate.

3. The ejection apparatus of claim 1, wherein a distance between the ejection hole of the first nozzle closest to the second nozzle and the ejection hole of the second nozzle closest to the first nozzle is set to be equal to or less than twice a maximum distance between adjacent ejection holes among the plurality of ejection holes of each of the first nozzle and the second nozzle.

4. The ejection apparatus of claim 1, wherein a diameter of at least one among the plurality of ejection holes of the first nozzle is set to be greater than a thickness of the front surface of the first nozzle, and a diameter of at least one among the plurality of ejection holes of the second nozzle is set to be greater than a thickness of the front surface of the second nozzle.

5. The ejection apparatus of claim 1, wherein the first nozzle and the second nozzle are mirror-symmetrical.

6. The ejection apparatus of claim 1, wherein the front surface of each of the first and the second nozzles is a convex surface curved toward the substrate over an entire area where the plurality of ejection holes are arranged.

7. The ejection apparatus of claim 3, wherein a distance between the front surface of each of the first and the second nozzles and the substrate increases as the first and the second nozzles are spaced farther apart from each other.

8. The ejection apparatus of claim 1, wherein the front surface of each of the first and second nozzles is provided with:
a first flat structure facing toward a first direction away from a reference plane defined between the first nozzle and the second nozzle;
a second flat structure facing toward a second direction farther away from the reference plane than the first direction; and
a connecting surface connecting the first flat structure and the second flat structure and facing toward a direction approaching the reference plane, and
wherein one among the plurality of ejection holes is perforated in each of the first flat structure and the second flat structure.

9. The ejection apparatus of claim 8, wherein an angle between a normal to the connecting surface and a normal to each of the first flat structure and the second flat structure is 90° or less.

10. The ejection apparatus of claim 1, wherein each of the first nozzle and the second nozzle is provided with a back surface which is a cylindrical surface along an inner surface of a process chamber provided in a manner concentric with the substrate or a planar surface formed in a similar manner as the cylindrical surface.

11. The ejection apparatus of claim 1, wherein a set of the plurality of ejection holes is provided in a multistage manner corresponding to a plurality of substrates comprising the substrate arranged in a direction substantially perpendicular to the substrate.

12. The ejection apparatus of claim 1, wherein opening areas of ejection holes located at both ends of the plurality of ejection holes are set to be greater than opening areas of ejection holes adjacent thereto.

13. A substrate processing apparatus comprising:
a process vessel in which a substrate is accommodated;
the ejection apparatus of claim 1 arranged in the process vessel; and
an exhaust structure opened to directly face at least one of the plurality of ejection holes of the first nozzle and at least one of the plurality of ejection holes of the second nozzle with a central axis of the substrate therebetween, wherein the gas ejected through each of the first nozzle and the second nozzle is exhausted through the exhaust structure.

14. The substrate processing apparatus of claim 13, wherein the gas is supply in a flash flow manner using the ejection apparatus.

15. The substrate processing apparatus of claim 14, wherein an average flow velocity of the gas supplied in the flash flow manner from the ejection apparatus is set to be 10 m/s or more on a predetermined plane parallel to the substrate in the process vessel.

16. The substrate processing apparatus of claim 14, wherein the gas supplied in the flash flow manner from the ejection apparatus is ejected such that the first source gas is diffused radially at flow velocities with peaks in at least five different directions on a predetermined plane parallel to the substrate in the process vessel.

17. The substrate processing apparatus of claim 14, further comprising
an exhauster configured to be capable of exhausting an inner atmosphere of the exhaust structure such that a pressure of the exhaust structure is maintained at 300 Pa or less while the gas is supplied in the flash flow manner.

18. A substrate processing method comprising:
(a) ejecting a gas onto a substrate through a plurality of ejection holes of each of a first nozzle and a second nozzle, wherein each of the first nozzle and the second nozzle faces a peripheral edge of the substrate and extends in a direction perpendicular to a main surface of the substrate, wherein the plurality of ejection holes of each of the first nozzle and the second nozzle are arranged on a front surface of each of the first nozzle and the second nozzle in a direction parallel to the main surface of the substrate, and wherein the front surface of each of the first nozzle and the second nozzle is continuously formed on a side facing the substrate; and
(b) ejecting the gas through an ejection hole of the first nozzle closest to the second nozzle among the plurality of ejection holes of the first nozzle and an ejection hole of the second nozzle closest to the first nozzle among the plurality of ejection holes of the second nozzle, wherein the ejection hole of the first nozzle closest to the second nozzle and the ejection hole of the second nozzle closest to the first nozzle are formed on substantially a same tangent plane such that the gas is ejected from the first nozzle in a direction substantially parallel to the gas ejected from the second nozzle, and wherein, when a direction from a center of an arrangement of the first and second nozzles toward a center of the substrate is defined as a reference direction, the front surface of each of the first nozzle and the second nozzle is formed such that an angle of a normal to the front surface relative to the reference direction at positions where the plurality of ejection holes are located increases in an arrangement order of the plurality of ejection holes.

19. A method of manufacturing a semiconductor device, comprising
the method of claim 18.

20. A non-transitory computer-readable recording medium storing a program that causes a substrate processing apparatus, by a computer, to perform a process comprising the method of claim 18.
